(19) United States
(12) Patent Application Publication
(10) Pub. No.: US 2024/0417849 A1
(43) Pub. Date: Dec. 19, 2024

(54) CHEMICAL VAPOR DEPOSITION OF DIBORIDE ALLOY COATINGS

(71) Applicant: The Board of Trustees of the University of Illinois, Urbana, IL (US)

(72) Inventors: Kinsey CANOVA, Urbana, IL (US); John R. ABELSON, Urbana, IL (US); Gregory S. GIROLAMI, Urbana, IL (US); Jessica Anne KROGSTAD, Urbana, IL (US); Samyukta SHRIVASTAV, Urbana, IL (US)

(21) Appl. No.: 18/671,037

(22) Filed: May 22, 2024

Related U.S. Application Data
(60) Provisional application No. 63/468,175, filed on May 22, 2023.

(51) Int. Cl. C23C 16/38; C23C 16/46

(52) U.S. Cl. CPC C23C 16/38; C23C 16/46

(57) ABSTRACT

Systems and methods to grow transition metal diboride alloys by chemical vapor deposition (CVD) from two precursors: a boron-containing precursor and a boron-capturing agent. The deposited metal diboride alloy may have the formula Hf₁₋ₓAlₓB_{y}. An exemplary method for forming a diboride alloy coating on a surface via chemical vapor deposition may include contacting the surface with a boron-containing precursor and a boron-capturing agent; heating the surface, the boron-containing precursor, and the boron-capturing agent to a temperature of less than or equal to 750° C.; and forming the diboride alloy coating on the surface.

### CROSS-REFERENCE TO RELATED APPLICATIONS

This application claims the benefit of priority to U.S. Provisional Patent Application No. 63/468,175, filed May 22, 2023, which is hereby incorporated by reference in its entirety.

### STATEMENT REGARDING FEDERALLY SPONSORED RESEARCH OR DEVELOPMENT

This invention was made with government support under Award Number 19-14769 awarded by the National Science Foundation. The government has certain rights in the invention.

### BACKGROUND OF INVENTION

Transition metal diborides are desirable coating materials in extreme environments due to their high hardness, high melting temperature, and diffusion barrier properties. These properties make them appropriate for many applications, such as coatings for hypersonic aircraft, solar absorbing energy devices, and as diffusion barriers in electronics. However, at moderate temperatures (700° C.) in oxidizing environments, these coatings become unstable due to formation of B₂O₃, which melts above 450° C. and becomes volatile at temperatures below 1000° C. Oxidation resistance of transition metal borides has been improved by alloying with other elements, including SiC, W, Al, and Al-containing compounds, these ternary or quaternary alloy compounds help form protective oxide layers near the surface that prevent complete oxidation of the underlying film.

Many of these transition metal diboride-based alloys are prepared by pressed powder sintering, but this may not afford well-mixed alloys due to low solid solubility and low diffusivity between the starting materials. Alternatively, physical vapor deposition (PVD) methods such as magnetron sputtering are often used to make well-mixed coatings, and these can have good smoothness and low fabrication cost. Film are usually crystalline, with grains primarily oriented in a single direction relative to the substrate. Despite the advantages, PVD has a few drawbacks: For one, the metal:B stoichiometry is difficult to control, since it depends entirely on the flux of sputtered atoms, and no chemical pathway regulates the relative metal and B composition during growth. PVD processes are not generally conformal, so coating curved surfaces such as bearings, electrical contacts, and machining tools may involve components of conformal chemical vapor deposition in their film growth. PVD metal diboride coatings often have an as-deposited columnar morphology that is associated with anisotropic mechanical properties and transport of corrosive materials along column boundaries.

Thus, the as-deposited morphology may provide pathways for the very corrosion that barrier coating are intended to protect against. These limitations leave an ongoing need for new fabrication methods affording homogeneous, dense alloy coatings with good step coverage.

Accordingly, it can be seen from the foregoing that there is a need for improved systems and methods for transition metal diboride coatings.

### SUMMARY OF THE INVENTION

Presented are systems and methods to grow transition metal diboride alloys, by chemical vapor deposition (CVD) from two precursors: a boron-containing precursor and a boron-capturing agent. In one aspect, the deposited metal diboride alloy has the formula Hf₁₋ₓAlₓB_{y}. In one aspect, the deposited metal diboride alloy has the formula Ti₁₋ₓAlₓB_{y}. In one aspect, the deposited metal diboride alloy has the formulaTi₁₋ₓAlₓB_{y}. In one aspect, the deposited metal diboride alloy has the formula Zr₁₋ₓAlₓB_{y}. In one aspect, the deposited metal diboride alloy has the formula Cr₁₋ₓAlₓB_{y}. In one aspect, x is from 0.3 to 0.6, for example, x may be about (±10%) 0.4. In one aspect y is from 1.8 to 3, for example y may be about (±10%) 2.

The growth of pure HfB₂ from Hf(BH₄)₄ has been studied in great detail to show highly surface reaction rate-limited growth at low temperatures (≤300° C.). Results presented here show that the overall Hf₁₋ₓAlₓB_{y} growth rate, during co-flow of Al precursor AlH₃·NMe₃ (TMAA, Me=CH₃), is faster than the sum of rates for the two precursors alone. The rate enhancement was studied by conducting experiments to rule out possible mechanisms, such as gas-phase reactions, and the collection of experimental results shows that Hf and Al incorporation rates are coupled, which extends to a relatively stable alloy composition of x˜0.4. Diffraction measurements for film crystallinity indicate formation of a substitutional solid solution of the mixed metal diboride. This is particularly notable since the HfB₂ films grown from Hf(BH₄)₄ alone at or below 300° C. are essentially amorphous, and the polycrystalline solid solution of Hf₁₋ₓAlₓB₂ has not been experimentally measured before. In some embodiments, the coating has good conformality on trenches at depth:width (aspect) ratios up to 6, which is desirable for coating nonplanar surfaces. The film microstructure indicates good hardness because, as shown below, the films do not contain elemental Al phases, and deposited films have equiaxed grains with no columns or phase segregation. Without wishing to be bound by theory, the analysis below suggests that Al reacts with rate-limiting BHx surface species, which are intermediates in HfB₂ deposition, to support the improved growth rate and alloy crystallinity.

In one aspect, the growth of nanocrystalline Hf₁₋ₓAlₓB_{y} coatings proceeds at temperatures s 300° C. by chemical vapor deposition from two precursors: Hf(BH₄)₄ and AlH₃N(CH₃)₃. Pure HfB₂ grown by this method is x-ray amorphous and under-dense, whereas Hf₁₋ₓAlₓB_{y} is nanocrystalline. Hf₁₋ₓAlₓB_{y} films grow faster, measured in terms of incorporated metal atoms per area per time, than the sum of the growth rates from the precursors when used individually. At temperatures s 250° C., the incorporation rate of Al, which is proportional to Al precursor flux, largely determines (and enhances) the incorporation rate of Hf in HfB₂. At temperatures >250° C., the growth rate and composition are functions of both precursor fluxes, yet the enhancement in growth rate during alloying persists.

In one aspect, the growth of nanocrystalline Ti₁₋ₓAlₓB_{y} coatings proceeds at temperatures ≤300° C. by chemical vapor deposition from the precursors Ti(BH₄)₃(dme), wherein dme is 1,2-dimethoxyethane or similar ethers and AlH₃N(CH₃)₃.

In one aspect, the growth of nanocrystalline Zr₁₋ₓAlₓB_{y} coatings proceeds at temperatures s 300° C. by chemical vapor deposition from the precursors Zr(BH₄)₄ and AlH₃N(CH₃)₃.

In one aspect, the growth of nanocrystalline Cr₁₋ₓAlₓB_{y} coatings proceeds at temperatures s 300° C. by chemical vapor deposition from the precursors Cr(B₃H₈)₂ and AlH₃N(CH₃)₃.

Without wishing to be bound by theory, it is postulated that the increased deposition rate and improved crystallinity are due to the elimination of a rate limiting surface reaction. For example, to form HfB₂ from Hf(BH₄)₄, two of the four BH₄ ligands on the precursor donate their B atoms to the film, but the other two must eliminate two equivalents of B by formation and desorption of B₂H₆; however, previous work shows that B₂H₆ may be unstable on surfaces at these temperatures, making its removal a rate-liming process. When Al is added to the growth surface, it can react with the excess B to incorporate AlB₂ into the solid, thus overcoming the surface rate limitation. In the limit where AlB₂ formation is much faster than B₂H₆ release, the Hf:AI ratio should be “locked” close to 1:1; experimental data at temperatures s 250° C. are consistent with this prediction. In addition, Al enables nanocrystallinity in the as-deposited film. Two routes may impart nanocrystallinity in the alloy films. It is possible that pure HfB₂ films are slightly overstoichiometric in B, which spoils grain growth; but Al incorporation corrects the stoichiometry by consuming excess surface B, and nanocrystals form. It is also possible that the relatively high surface diffusivity of aluminum facilitates crystal formation.

Without wishing to be bound by any particular theory, there may be discussion herein of beliefs or understandings of underlying principles relating to the devices and methods disclosed herein. It is recognized that regardless of the ultimate correctness of any mechanistic explanation or hypothesis, an embodiment of the invention can nonetheless be operative and useful.

### BRIEF DESCRIPTION OF THE DRAWINGS

FIG. 1: Incorporation rates for Hf and Al in pure HfB₂, Al, and alloy films grown from about 0.15 mTorr Hf(BH₄)₄ and 0.02 mTorr TMAA are shown versus the deposition temperature. Incorporation rate is calculated from the RBS areal density for each metal atom and the growth time; each data point comes from a single experiment.

FIG. 2: Al and Hf incorporation rates are plotted against each other to show correlation between these rates. Data are distinguished by growth temperatures, ranging from 225 to 300° C. Arrows point to outliers from the trend on the graph; these correspond to higher Hf(BH₄)₄ fluxes than the other films grown at that temperature. Each data point corresponds to a single experiment.

FIG. 3: Composition x in Hf₁₋ₓAlₓB_{y} is plotted as a function of the Hf(BH₄)₄ flux for the temperatures studied. Lines serve to guide the eye.

FIGS. 4A-4D: SIMS ion counts for B, Al, Si, and Hf are plotted versus sputter time for the three films under investigation. FIG. 4A: Film grown from Hf(BH₄)₄ alone at 300° C. (sample #1062). FIG. 4B: Alloy film grown at 300° C. (sample #1066). FIG. 4C: Layered film comprising an alloy top surface and film grown from Hf(BH₄)₄ alone next to the substrate (sample #1078). Schematic representations of RBS compositional profiles are shown in FIG. 40, and section heights are proportional with the number of layers (×10¹⁵ at. cm⁻², ˜ thickness) used in RBS fitting.

FIG. 5: Cross-sectional TEM shows the homogeneous morphology of a film grown at 300° C. and relatively low precursor pressures, 0.13 mTorr Hf(BH₄)₄ and 0.015 mTorr TMAA. The substrate, film thickness, and protective top layer (from TEM preparation) are indicated.

FIG. 6A: Grazing incidence XRD indicates crystallinity in films grown at 250 or 300° C., labeled as: 1, Hf_{0.6}Al_{0.4}B₂ grown at 250° C.; 2, Hf_{0.6}Al_{0.4}B₂ grown at 300° C.; 3, HfB₂ grown at 300° C. Peak locations for pure bulk HfB₂ (dashed lines) and AlB₂ (dotted lines) are indicated for the three most intense peaks; less intense peaks from 50°-70° are consistent with those crystal structures. FIG. 6B: Lattice parameters a and c for the hexagonal crystal structure calculated from the alloy diffractograms are shown in comparison to literature reference parameters for pure HfB₂ and AlB₂. Dotted lines show lattice parameters calculated by Vegard's law from the alloy composition.

FIGS. 7A-7D: Cross-sectional SEM of films grown at 250° C. on trenched substrates show excellent step coverage in features of aspect ratio 3 (top) and 6 (bottom). Coverage of pure HfB₂ films is shown in FIGS. 7A-7B, and coverage of alloy films is shown in FIGS. 7C-7D. The scale is the same for all images.

FIG. 8: B:Hf from SIMS data are plotted versus sputter time for all three samples identified in FIGS. 4A-4D. Sample 1062 is pure HfB₂ deposited at 300° C., sample 1066 is Hf_{0.6}Al_{0.4}B_{y} deposited at 300° C. with a thin HfB₂ layer near the substrate, and sample 1078 is a layered sample comprising Hf_{0.6}Al_{0.4}B_{y} near the surface (sputter time 0-320 s) and HfB₂ at the substrate interface (sputter time 320-480 s). The continuous decline at long sputter times occurs when the substrate is reached.

FIG. 9 shows the microstructure of the diboride coatings as a function of increasing aluminum content.

FIG. 10A: The RBS spectrum shows the compositional depth profile for an Al-doped TiB₂ film grown at 225° C. on sapphire. Peak locations are indicated on the spectrum; some chlorine contamination in the film is possible because chloride precursors are used for preparation of Ti(BH₄)₃(dme). FIG. 10B: A schematic illustration of the fit layer profile is below the spectrum, showing the relative thickness and composition of grown layers. Cl incorporation (from impurities in the precursor) of 1-2% is omitted from the displayed composition.

FIG. 11A: The RBS spectrum shows the compositional depth profile for an Al-doped TiB₂ film grown at 200° C. on Si. RBS counts are shown as points, and the simulated compositional provile is shown as a curve. Peak locations are indicated on the spectrum. FIG. 11B: A schematic illustration of the fit layer profile is below the spectrum, showing the relative thickness and composition of grown layers.

FIG. 12: High resolution HAADF image for coating B of example 4.

FIGS. 13A-13D: Plan-view SEM of the ˜50 nm thick Hf_{0.62}Al_{0.38}B_{y} film (Coating B) grown on sapphire (FIG. 13A) as-deposited and annealed to (FIG. 13B) 700, (FIG. 13C) 800, and (FIG. 13D) 900° C.

FIGS. 14A-14C: Cross-sectional TEM shows the effect of annealing on oxidation for (FIG. 14A) the as-deposited film B, (FIG. 14B) film B annealed to 700° C., and (FIG. 14C) film B annealed to 700° C. with an isothermal hold for one hour.

FIG. 15A: The composition profile for as deposited Coating B show a uniform elemental distribution within the film, and a native oxide mainly composed of boron oxide, hafnium oxide and some aluminum oxide. The hafnium to aluminum ratio is 1.63:1. FIG. 15B: The composition profile after heating Coating B to 700° C., with no isothermal hold. FIG. 15C: The composition profile after heating Coating B at 700° C., with a 1-hour isothermal hold. Note that the aluminum content in the oxide layer has surpassed the hafnium content.

FIGS. 16A-16B: Cross-sectional TEM shows the effect of annealing on oxidation for (FIG. 16A) Coating B annealed to 800° C., and (FIG. 16B) Coating B annealed to 900° C., both without an isothermal hold. The film in FIG. 16A shows the cross section of an aluminum borate needle, with the hafnia crystallites embedded within the needle. The sapphire and film interface looks flat and uniform. The film cross section in FIG. 16B shows a well-developed aluminum borate needle. The sapphire interface is no longer planar.

FIGS. 17A-17B: Cross sectional TEM micrograph of an unalloyed HfB_{y} Coating A showing (FIG. 17A) the as received 100 nm thick coating and (FIG. 17B) the completely oxidized coating after annealing to 700° C. with a 1 hour isothermal hold.

FIG. 18A: SEM image of unalloyed HfB_{y} Coating A following heat treatment at 700° C. for 1 hour. The significant population of contraction cracks arose from simultaneous crystallization and oxidation. FIG. 18B: SEM image of Coating C with excess aluminum, showing a distribution of nodular features on the surface, after the same heat treatment.

FIGS. 19A-19B: Cross sectional TEM micrograph of a Coating C showing (FIG. 19A) the as received 100 nm thick coating and (FIG. 19B) the coating after annealing at 700° C. with an isothermal hold of 1 hour.

FIG. 20A: TEM micrograph of Coating C heat treated to 700° C., with an isothermal hold of 1 hour. This sample was taken across the nodular features visible in FIG. 7B. The two inset boxes from left to right correspond to FIGS. 20B and 20C. FIG. 20B: EDS map of the nodule, which shows that it is mainly made of aluminum and oxygen. FIG. 20C: EDS map from the coating near this nodule, showing aluminum depletion and oxygen ingress due to the nodule breaching the oxide layer. This would be a possible failure mechanism that results in the breakdown of the oxide layer.

### STATEMENTS REGARDING CHEMICAL COMPOUNDS AND NOMENCLATURE

In general, the terms and phrases used herein have their art-recognized meaning, which can be found by reference to standard texts, journal references and contexts known to those skilled in the art. The following definitions are provided to clarify their specific use in the context of the invention.

As used herein, the term “boron-capturing agent” means a gaseous diboride alloy precursor configured to react with excess B on the surface of a substrate and 15 incorporate the B into a diboride alloy coating. In one embodiment, the boron-capturing agent may comprise aluminum. For example, in one embodiment, the boron capturing agent is trimethylamine alane (TMAA). In other embodiments the boron-capturing agent comprises chromium and/or magnesium.

As used herein, the term “boron-containing presursor” means a gaseous diboride alloy precursor configured to deliver boron to the surface of a substrate. In one embodiment, the boron-containing precursor is Hf(BH₄)₄. In one embodiment, the boron-containing precursor is Ti(BH₄)₃(dme), wherein dme is 1,2-dimethoxyethane. In one embodiment, the the boron-containing precursor is Zr(BH₄)₄. In one embodiment, the the boron-containing precursor is Zr(BH₄)₄. In one embodiment, the the boron-containing precursor is Cr(B₃H₈)₂.

As used herein, the term “nanocrystalline” means a crystalline material having a grain size below about 100 nm.

In an embodiment, a composition or compound of the invention, such as an alloy or precursor to an alloy, is isolated or substantially purified. In an embodiment, an isolated or purified compound is at least partially isolated or substantially purified as would be understood in the art. In an embodiment, a substantially purified composition, compound or formulation of the invention has a chemical purity of 95%, optionally for some applications 99%, optionally for some applications 99.9%, optionally for some applications 99.99%, and optionally for some applications 99.999% pure.

### DETAILED DESCRIPTION OF THE INVENTION

In the following description, numerous specific details of the devices, device components and methods of the present invention are set forth in order to provide a thorough explanation of the precise nature of the invention. It will be apparent, however, to those of skill in the art that the invention can be practiced without these specific details.

The invention can be further understood by the following non-limiting examples.

### Example 1: Formation of Hf₁₋ₓAlₓB_{y} Coatings

### Experimental Methods

Deposition experiments used a cold wall, turbopumped chamber of high vacuum construction that is described in detail elsewhere 35. Tetrakis(hydroborato) hafnium (Hf(BH₄)₄) is a convenient single-source precursor for the deposition of HfB₂ films^{33, 34}. Trimethylamine alane (AlH₃NMe₃, TMAA) was co-flowed as the Al precursor. Hf(BH₄)₄ was prepared following a literature route³⁶, and TMAA was purchased from Gelest and used as received. Both precursors are highly volatile at room temperature and are used without additional heating. A capacitance manometer measured precursor pressures in the chamber which were controlled by needle valves on each precursor inlet. Precursor inlets into the deposition chamber were oriented towards the substrate, causing a large fraction of the incoming flux to be forward-directed, i.e., a large fraction of the flux arrived in directions nearly perpendicular to the substrate³⁷. Most experiments used Si (100) substrates, degreased in acetone-isopropanol-water.

Conformality experiments used substrates with trenches etched into SiNx that was supported on a Si wafer; the trenches had aspect ratios up to 12.5. Spectroscopic ellipsometry (Woollam M-88) monitors film growth in-situ, from which an optical model for the alloy films provides a rough estimate for total thickness (exact measurements require film models that are tailored to alloy composition).

Ex-situ characterization was the primary source for information regarding film thickness, growth rate, and microstructure. Film profiles from Rutherford backscattering spectrometry (RBS, NEC Pelletron accelerator) were fit using SIMNRA software to determine composition. These fit profiles provide an areal density of atoms in the film, and these values for Hf and Al are used with the film growth time to calculate the average growth rate in units nm⁻² s⁻¹. Growth rate was measured by flux of each metal to compare individual precursor reaction rates; film thickness per se is a less useful parameter because it would not include information about composition, and film density may vary among experiments. Further, the Al incorporation (growth) rate can be measured more precisely than the relatively low TMAA pressures used during growth, so Al incorporation rate is used in lieu of TMAA flux in rate analysis. Experiments show that Al incorporation rate is roughly proportional to TMAA flux. The higher Hf(BH₄)₄ pressures were measured precisely by the manometer, and pressures were converted to fluxes for ease of comparison. In reality, the true precursor flux from forward-directed inlets exceeds that measured by the manometer³⁷, but, due to primarily surface reaction-limited growth from Hf(BH₄)₄, this does not affect the overall results.

Microstructure was measured using grazing incidence x-ray diffraction (XRD, Bruker D8 Advance) using Cu Kα radiation at an incidence angle of 1°. Cross sectional transmission electron microscopy (TEM, FEI Themis Z) in bright field mode shows film morphology on planar substrates, and cross-sectional scanning electron microscopy (SEM, Hitachi S4800) was used to determine coverage in trenches.

B concentration is difficult to quantify with good precision due to its low mass and atomic number³⁸. The RBS data are insufficient to quantify B concentration due to overlap with the Si substrate peak; fitting data in SIMNRA tends to overestimate B concentration, with B:Hf ratios sometimes exceeding 4, a physical limit based on precursor stoichiometry. Past studies of thermal decomposition <300° C. from Hf(BH₄)₄ alone measured B:Hf to be between 1.5 (X-ray photoelectron spectroscopy quantified by instrumental sensitivity factors)³³ and 3.5±0.5 (Auger electron spectroscopy with a reference standard)³⁹, yet it is assumed that B:Hf is ˜2. B stoichiometry is not essential to the analysis of growth rate and composition in terms of metal incorporation, which is 1:1 with precursor reaction rate, so the films are referred to as HfB₂ for growth from Hf(BH₄)₄ alone and Hf₁₋ₓAlₓB_{y} for the alloy films in the corresponding discussion. However, the analysis of rate limiting features in this system requires analysis of the relative B concentration; this was performed using time of flight secondary ion mass spectroscopy (SIMS, PHI Trift III). SIMS uses Au⁺ for the analysis ion beam and O₂⁺ for sputter depth profiling, and WinCadence software collects and quantifies the elemental ion counts. There is no standard sample to quantify SIMS data with; comparisons are shown between relative ion yield from atomic components.

### Growth Rate and Composition

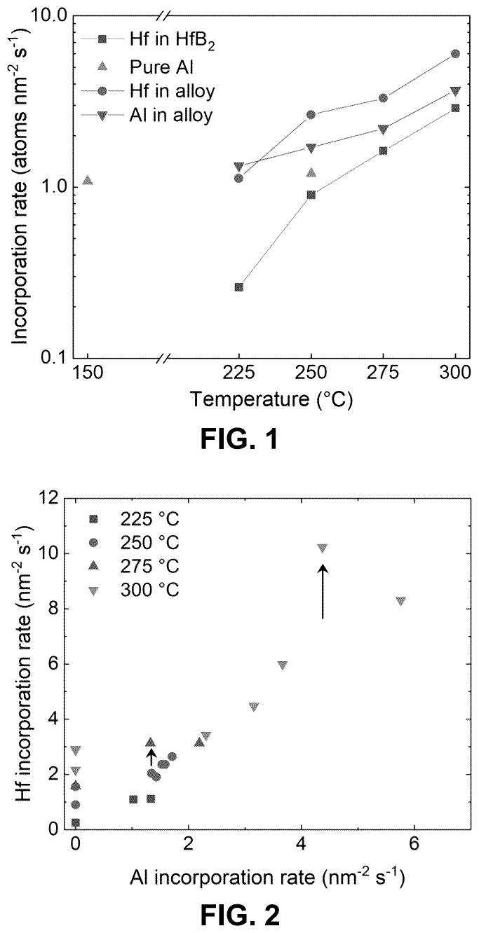

To establish the growth rates of these films, alloys were grown from about 0.15 mTorr Hf(BH₄)₄ and 0.02 mTorr TMAA over a range of temperatures from 225 to 300° C. (FIG. 1). The Hf incorporation rate for HfB₂ growth without TMAA (Hf in HfB₂) establishes a baseline over this temperature range, which substantially increases during co-flow with TMAA (Hf in alloy). Hf incorporation rates increase with temperature in both cases, consistent with thermally-activated (Arrhenius) growth 34. At 300° C., the Hf(BH₄)₄ reaction probability is about 0.01. Aluminum incorporation rate appears to be flux-limited based on equal incorporation rates at 150 and 250° C., associated with a reaction probability of ˜0.03. The data for alloy growth indicate strong effects on growth rates: Precursor co-flow increases the incorporation (growth) rate from both precursor species compared to the growth of each precursor alone. This effect is mild for TMAA at low temperatures, but its incorporation rate is nearly tripled at 300° C. On the other hand, the effect of adding TMAA for alloy growth at 225° C. more than quadruples the incorporation rate of Hf from Hf(BH₄)₄; the enhancement in incorporation rate persists to 300° C., albeit at a smaller magnitude, with a doubled incorporation rate.

Without wishing to be bound by theory, the increase in Hf incorporation rate appears to be tied to the Al incorporation rate. At 225° C., the growth of Hf is about 1:1 with Al; at 250° C., the Hf incorporation rate appears to be the sum of a 1:1 interaction between Hf(BH₄)₄ and TMAA (or its product, Al) and the thermal growth rate of HfB₂ without Al (FIG. 1), assuming no competitive surface kinetics are present. If the reaction probability of TMAA is constant, than it is predicted that an increase in TMAA flux would also increase the Hf incorporation rate. FIG. 2 plots this comparison in incorporation rates from several experiments that combine variations in fluxes and temperatures. At 300° C., Hf(BH₄)₄ pressures were varied a small amount and TMAA pressures varied from 0.02-0.06 mTorr to show whether Hf incorporation is tied to Al incorporation; the results show strong correlation, supporting the hypothesis. At 250° C., constant TMAA pressure of 0.02 mTorr was used with a range of Hf(BH₄)₄ pressures spanning 0.08-0.40 mTorr. Al incorporation varies according to small variations in TMAA flux (below instrument sensitivity); notably, high Hf(BH₄)₄ fluxes neither increase the Hf incorporation rate nor inhibit Al deposition. The lack of Al inhibition rules out a simple competitive adsorption model for the interaction between the two precursors. In general, the trend between Hf and Al incorporation rates is largely independent of variations in precursor fluxes and temperature, and the highest overall incorporation rates are achieved during growth with higher Al incorporation rates, from higher TMAA fluxes. Separate experiments in high (˜Torr) pressure, unpumped CVD corroborate the faster alloy growth rate compared to the separate precursors, and these indicate no effects of gas phase reaction between the precursors.

A couple of apparent outliers from this trend are indicated by arrows on the graph: They occur only at temperatures 275° C. and Hf(BH₄)₄ pressure of 0.2 mTorr (the maximum of the pressure range tested for these temperatures). Because they occur at higher temperatures, where thermal reactivity of Hf(BH₄)₄ is larger, this may be attributed to the growth kinetics becoming more flux-limited. Consistent with this, no outliers appear at lower temperatures: At 250° C., the growth with up to 0.4 mTorr Hf(BH₄)₄ follows the trend described previously.

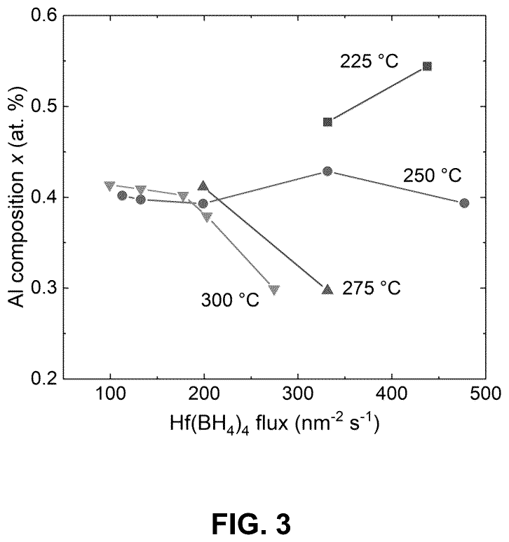

Composition of the alloy films grown between 25° and 300° C. is roughly similar, with x in Hf₁₋ₓAlₓB_{y} in the range of 0.40-0.44 (FIG. 3). As described in relation to relative metal incorporation rate, this appears to result from a 1:1 interaction between Hf and Al precursors plus the thermal growth of HfB₂ without Al, leading to the films being slightly more Hf-rich. For growth at temperatures 275° C., x decreases with increasing Hf(BH₄)₄ flux; as mentioned for the outliers in FIG. 2, Hf incorporation is less surface-reaction limited at higher temperatures, so increasing Hf(BH₄)₄ flux can increase Hf concentration relative to Al. For films grown at 225° C., Hf(BH₄)₄ thermal reactivity is significantly lower, yet x remains at 0.48-0.54. The composition of about 50% Al and 50% Hf suggests that Hf deposition is almost entirely dependent on a 1:1 interaction with alloying species. If the Hf incorporation rate was not coupled to the Al incorporation rate, and instead proceeded at its thermal reaction rate at 225° C., the expected Al composition x of the alloy grown at 225° C. would be 0.84.

To summarize these results for growth rate and composition, the experimental variables of interest and their results are described in a logic table (Table 1). Not noted in Table 1, but observable in the Figures, is that the incorporation rate of Al is generally proportional to TMAA flux, and this is not inhibited by high Hf(BH₄)₄ fluxes. These results provide guidelines for designing growth processes for a desired composition or growth rate: Films with x of 0.40-0.50 reproducibly grow at temperatures s 250° C. with TMAA plus equal or excess Hf(BH₄)₄. Above 250° C., film growth is approximately flux-limited. These experiments used excess Hf(BH₄)₄ flux relative to TMAA flux; since high Hf(BH₄)₄ fluxes do not inhibit Al incorporation after film nucleation, the Al concentration may be increased by increasing the TMAA flux, even though properties such as hardness will be degraded if Al-rich phases form²².

TABLE 1
Summary of growth rate and composition outcomes of
Hf₁₋ₓAlₓB_{y} CVD. Effects are sorted by variable of interest
and temperature, with all other growth conditions held constant.

| | | | Effect on growth rate from | |
|---|---|---|---|---|
| Variable | Temperature | | Hf(BH₄)₄ | Effect on Hf:Al ratio |
| Hf(BH₄)₄ flux, | 250° | C. | None observed | None observed |
| 0.1-0.4 mTorr | 275-300° | C. | Transition to flux-limited | Becomes more Hf-rich |
| TMAA flux, | 300° | C. | Increases linearly with Al | None observed |
| 0.02-0.06 mTorr | | | | |
| Temperature | 225° | C. | Proportional to Al | About 1:1 Hf:Al |
| | | | incorporation/TMAA flux | |
| | 250° | C. | Proportional to Al | About 1.6:1 Hf:Al |
| | | | incorporation plus thermal | |
| | | | growth rate on HfB₂ | |
| | 275-300° | C. | Transition to flux limited | Depends on relative |
| | | | | precursor fluxes |

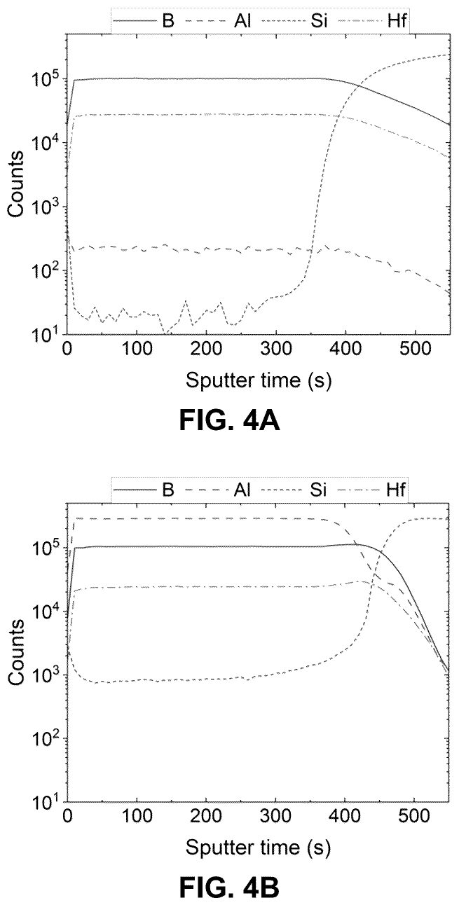

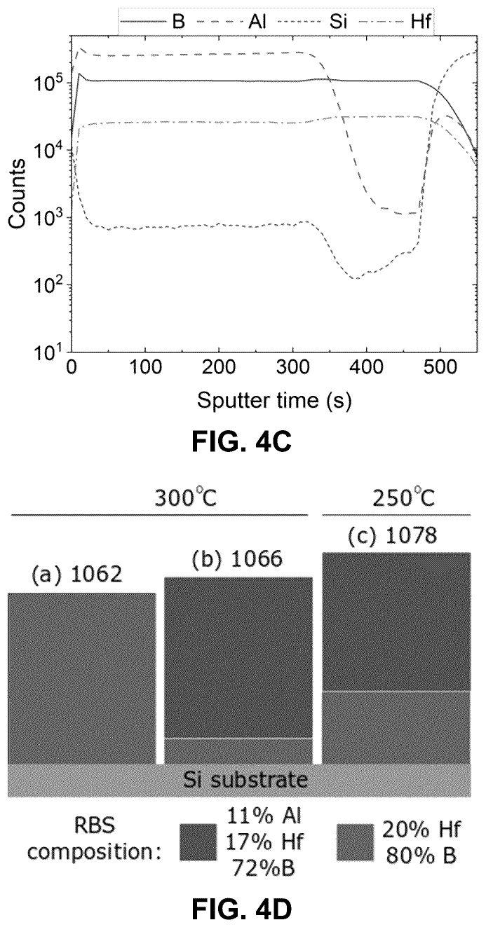

SIMS data for three films, representing film grown from Hf(BH₄)₄ alone and Hf(BH₄)₄ with TMAA at 250 or 300 00, are shown in FIG. 4, along with their composition through thickness according to RBS (FIG. 4D). The flatness of the curves for B, Hf, and Al indicate compositional homogeneity within each layer of the film. Any changes in counts per film ion occur at interfaces between (i) the surface and contaminants and alloy film, (ii) alloy and pure HfB₂ film (present in FIGS. 4B and 40), and (iii) reaching the Si substrate (all profiles). These may be considered to be artifacts of the relative sputter rates of each component. It should be noted that the Si peak, representing the substrate, is apparently increased when Al is present in the film; however, the Si counts include contributions from AlH⁺ ions.

### Morphology and Microstructure.

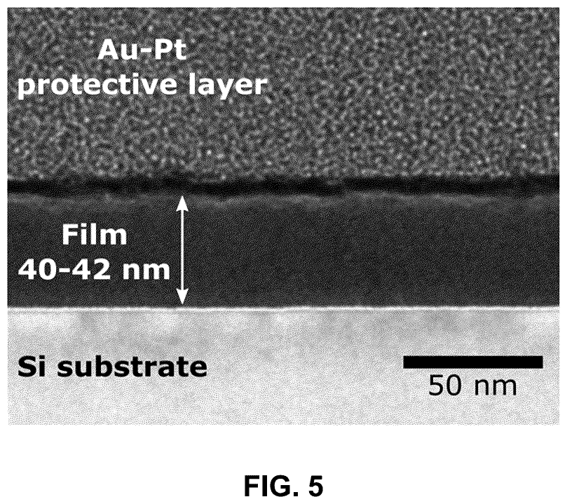

Alloy films have relatively smooth morphology, and alloying improves the metal sublattice density. Gross-sectional TEM of a representative alloy film, grown for three minutes at 300° C. from 0.13 mTorr Hf(BH₄)₄ and 0.02 mTorr TMAA, shows that films have smooth surfaces and are homogenous in the bulk, i.e., no columnar structures are present (FIG. 5). In terms of film thickness, this growth process has a growth rate of 14 nm min⁻¹. The density of the metal sublattice is calculated using cross-section film thickness and the atomic density of hafnium and aluminum measured in RBS. Pure HfB₂ films grown at 300° C. have a density of 17.2 Hf nm⁻³, which is ˜55% of bulk HfB₂ density; the alloy films have a metal sublattice density of 25.9 nm⁻³, which is 75% of the anticipated bulk density of Hf_{0.6}Al_{0.4}B₂ (alloy density estimated from a weighted average of AlB₂ and HfB₂).

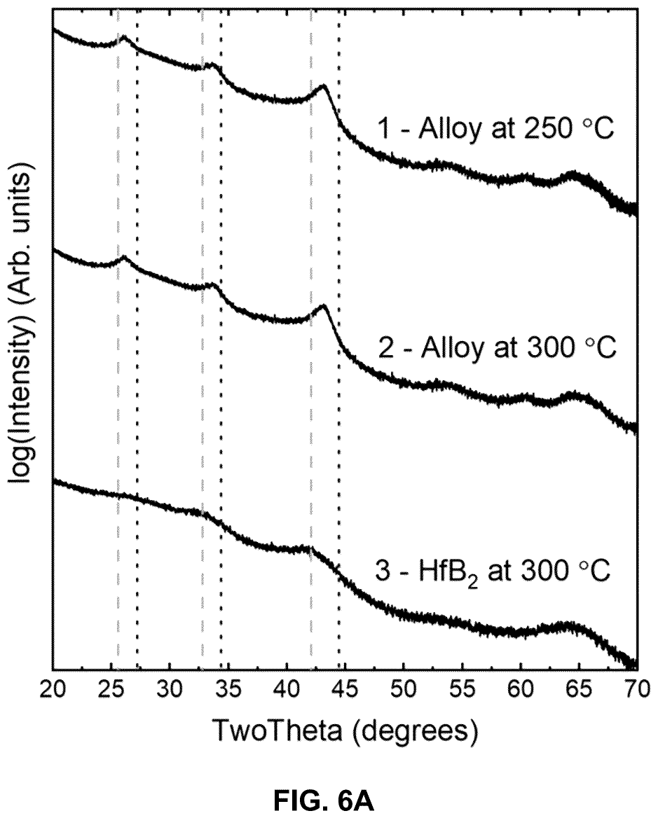

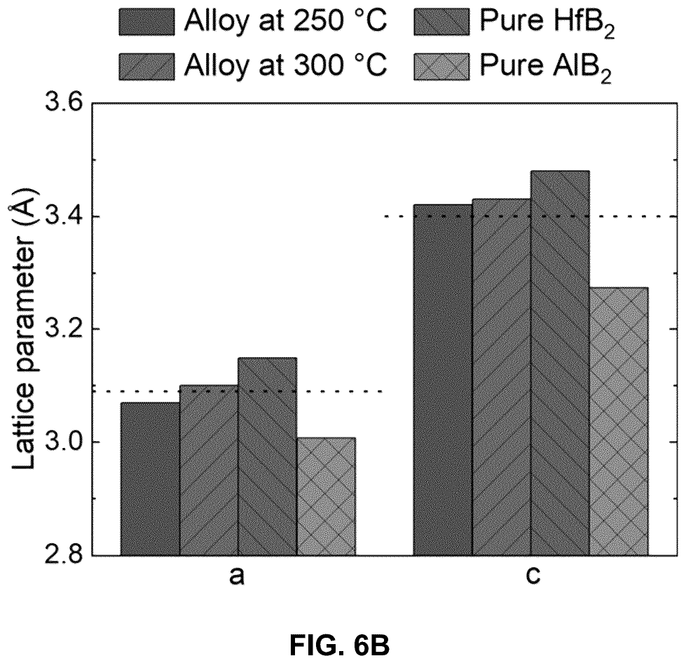

Film analysis using XRD shows that films deposited at 250 and 300° C. are nanocrystalline with an amorphous background (FIG. 6A). Locations of the crystalline peaks fall between the peaks for the hexagonal crystal structures of HfB₂⁴⁰ and AlB₂⁴¹; Table 2 provides lattice parameters of the alloy films and bulk HfB₂ and AlB₂ (visualized in FIG. 6B). Lattice parameters from the alloy films have excellent agreement with those calculated from Vegard's law. TEM characterization confirms the difference in crystallinity for unalloyed and alloyed films: Presence or absence of lattice fringes in cross sectional TEM, shown as spots in the fast Fourier transform (FFT) of the image, confirm the randomly oriented crystallinity in the alloy. The peak locations and relative intensity are similar for alloys grown on Si with native oxide and c-plane sapphire, indicating that crystallinity is independent of the substrate.

TABLE 2
Lattice parameters calculated from XRD data are compared
with bulk HfB₂, AlB₂, and the estimated parameters from
a Vegard's law calculation. Film measurements correspond
to a substitutional solid solution of Hf_{0.6}Al_{0.4}B₂.

| Parameter | a (Å) | c (Å) |
|---|---|---|
| Bulk HfB₂⁴⁰ | 3.15 | 3.48 |
| Bulk AlB₂⁴¹ | 3.007 | 3.274 |
| Hf_{0.6}Al_{0.4}B₂ (250° C.) | 3.07 | 3.42 |
| Hf_{0.6}Al_{0.4}B₂ (300° C.) | 3.10 | 3.43 |
| Hf_{0.6}Al_{0.4}B₂ (Vegard's law) | 3.09 | 3.40 |

Significantly, there is no evidence for crystalline domains of pure FCC Al (most intense peak near 2θ=38°), which is excellent in regard to film mechanical properties because metallic Al would severely diminish the peak hardness of these films. The lack of pure aluminum regions also indicates that the two-precursor CVD process is not dominated by growth from the more reactive precursor, TMAA. Previous results show that adsorbed Hf(BH₄)₄ can block sites for Al nucleation prior to HfB₂ growth⁴², which may help prevent formation of pure Al domains prior to HfB₂ nucleation.

Overall, the x-ray data show that alloying with aluminum affords a substitutional, nanocrystalline solid solution of Hf₁₋ₓAlₓB₂. Compared to the predominantly amorphous films grown from Hf(BH₄)₄ alone, which crack during annealing to 700° C. due to volume shrinkage upon crystallization, the alloys maintain their nanocrystalline microstructure and do not crack at 700° C.⁴². This is beneficial for potential applications as diffusion barriers and protective hard coatings at elevated temperatures.

### Coverage in Recessed Features

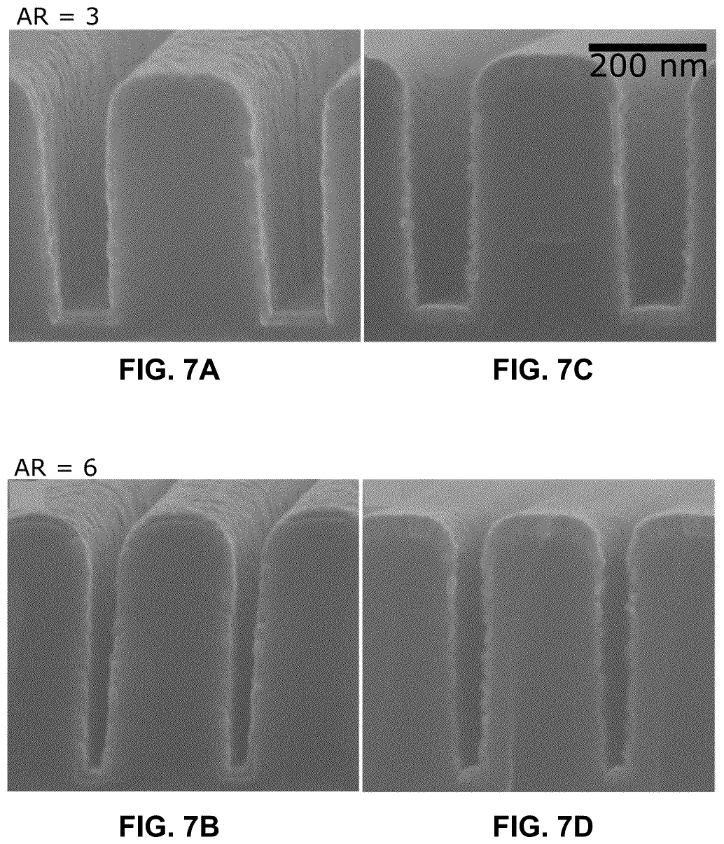

CVD is conformal when growth is carried out under surface reaction rate-limited (rather than flux-limited) conditions. This route for conformal growth has been modeled before using a Langmuirian framework, which is based on a near-saturation coverage of adsorbates as a result of relatively slow reaction or desorption, for HfB₂ growth in trenches or vias^{34, 42, 43}. In this way, a small fraction of the flux can adsorb at first impingement on the growth surface, which allows the remaining flux to reach the bottom of the trench by molecular flow between the feature walls. Increasing the precursor flux reaching the bottom of the trench improves the film step coverage (film thickness at the bottom of the trench divided by thickness at the top)⁴³. For example, a HfB₂ film grown from 0.12 mTorr precursor on trenches at 250° C. is highly conformal (FIGS. 7A-7B), reflecting the expected conformality.

Growth of the Hf₁₋ₓAlₓB₂ films has the advantage of relatively fast growth rates, but this can reduce conformality, i.e., growth rate of TMAA may be flux-limited.

Growth with high reaction rates is expected to behave similarly to PVD-grown films, where atoms stick to surfaces of first impingement. However, forward-directed flux improves the precursor flux arriving first at the trench bottom to improve conformality³⁷. In some embodiments, for this two-precursor system giving fast growth rates, forward-directed fluxes of both precursors may afford acceptably conformal films.

The result of six minutes of alloy growth, using 0.12 mTorr of Hf(BH₄)₄ and 0.02 mTorr of TMAA, on trench substrates at 250° C. is shown in FIGS. 7C-7D. Despite the fairly low fluxes and fast growth rates, coatings have uniform thickness along the sidewalls for trench depth/width (aspect) ratios up to 6. Growth begins to be sub-conformal at higher aspect ratios and longer growth times. The coating at the flat trench tops and bottoms is thicker than that on the sidewalls, which is evidence of the forward-directed flux that provides a narrow angular distribution of impinging precursor flux. For practical applications in small-scale devices requiring hard coatings, this result shows that nonplanar substrates can be coated through a combination of strategic precursor delivery and growth rates at least partially controlled by surface reactions.

### Discussion

The improved crystallinity and correlation between Hf and Al incorporation rates suggest that there is an important surface interaction between the precursors, their intermediates, or reaction products. From the literature, the precursors used in the experiments react to completion as follows^{33, 44}:

Hf(BH₄)₄(ads)→HfB₂(s)+B₂H₆(g)+5H₂(g)

AlH₃NMe₃(ads)→Al(s)+NMe₃(g)+1.5H₂(g) (1.2).

The fast deposition of Al from TMAA at temperatures as low as 150° C. from (2) indicates that the surface reaction to deposit Al is not the rate limiting step in alloy growth; also, neither of the gaseous products (NMe₃ and H₂) should decompose to alter the surface composition at the alloy growth temperatures^{45, 46}. Conversely, HfB₂ deposition is surface reaction-limited at the temperatures used in this study, and all growth temperatures are well above the temperature (123° C.) where rapid decomposition of B₂H₆ may occur⁴⁷. This decomposition, viewed as a reversible process, implies that the growth surface may remain covered in BHₓ, only rarely forming and desorbing B₂H₆; hence, the removal of B as B₂H₆ may be rate limiting in the case of pure HfB₂ growth. In earlier work on ZrB₂ deposition from Zr(BH₄)₄, poor film quality was attributed to incorporation of excess BHₓ⁴⁸. Here, it is postulated that the slow removal of boranes both hinders the growth rate and, via the incorporation of excess B, spoils the crystallinity of HfB₂.

When Al is present on the substrate during alloy deposition, a ratio of Hf and Al incorporation of about 60:40 is observed, which may be attributed to a 1:1 interaction between Hf and Al and Hf incorporation pushed higher from thermal growth from the excess Hf(BH₄)₄. The distinct crystal phase of Hf_{0.6}Al_{0.4}B₂ from XRD indicates that Al is incorporated within mixed metal diboride grains instead of as a separate, pure Al or AlB₂ phase. A reaction to form Al—B bonds is not unrealistic because Al can form bridging bonds with BH₄ that decompose to AlBₓ^{49, 50}, even though it was not discerned whether the surface interaction involves Al in the form of AlH₃ (from TMAA) or as Al metal and whether the reaction is with borohydride or other borane (BHₓ) surface species.

To explain the above, a surface reaction is proposed where the fast growth rates and Al—B bonding occur in mixed metal alloy growth from Hf(BH₄)₄ with Al,

Hf(BH₄)₄(ads)+AlH₃NMe₃(ads)→HfB₂(s)+AlB₂(s)+NMe₃(g)+9.5H₂(g) (3),

in which the proposed rate-limiting step to remove B as B₂H₆ is overcome by Al capturing that B to form AlB₂. For the purposes of this discussion, the interaction is treated as having 1:1 stoichiometry, which does not account for thermal deposition from Hf(BH₄) in the absence of TMAA or Al. This reaction outcome requires no formation of unstable byproducts (B₂H₆), and both metal diboride components of the alloy phase are formed. Additionally, this reaction is consistent with the absence of gas-phase interactions between the two precursors, Hf(BH₄)₄ and TMAA.

### Probing the B Capture Hypothesis

The hypothesis developed above, that Al may act to capture B by forming AlB₂ and thus overcome the rate-limiting step of removing B via the formation B₂H₆, can also be supported using existing Hf₁₋ₓAlₓB_{y} films by comparing B:Hf in HfB₂ and Hf₁₋ₓAlₓB_{y} films. In the pure HfB₂ films, B:Hf is essentially 2. In the alloy films, it is proposed that Al is reacting with BHₓ groups to form Al—B bonds, effectively capturing additional B in the film compared to the pure HfB₂. B:Hf would be greater than two, up to a physical maximum of 4 where all B in Hf(BH₄)₄ is incorporated. Without further processing of the SIMS data shown in FIG. 4, it can be observed, especially in the layer profile of FIG. 4C, that there is a minute difference in the relative B and Hf counts in the alloy vs. pure HfB₂ film.

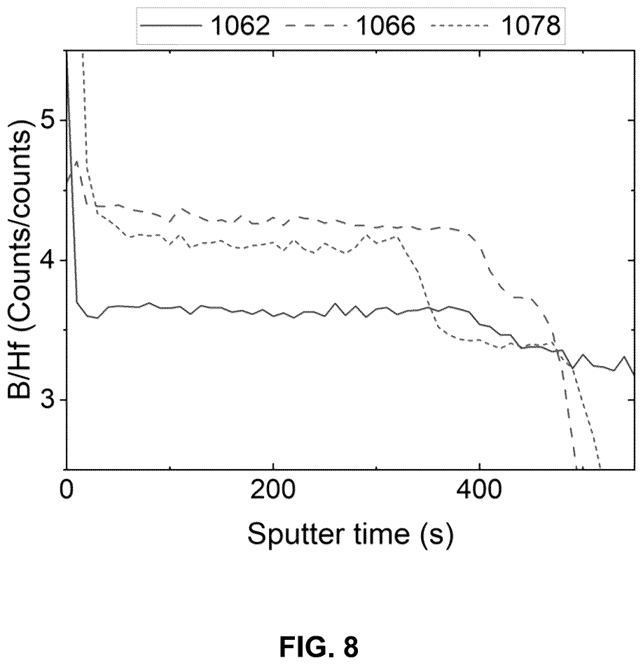

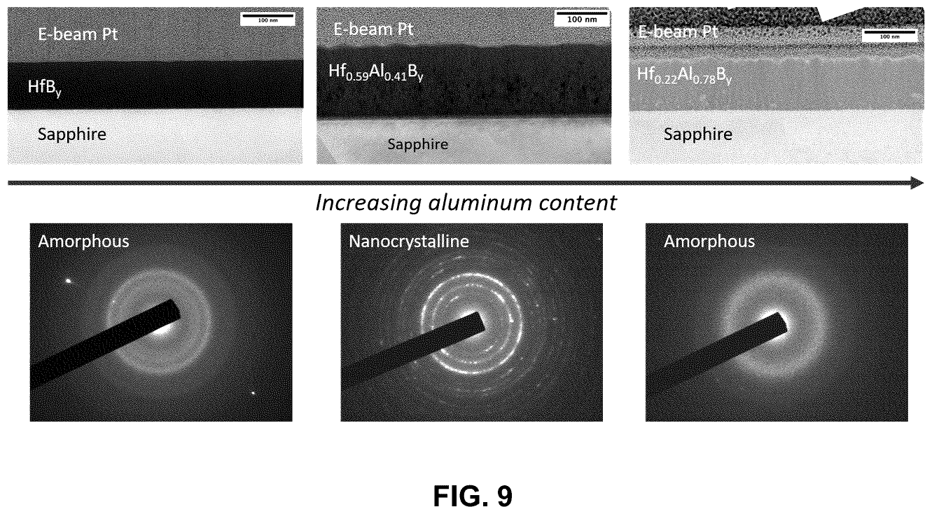

FIG. 8 shows B:Hf from SIMS data in the alloy and unalloyed films (data in FIG. 4). In samples 1062 and 1066, grown at 300° C., the alloying increases B:Hf from 3.6 (no Al) to 4.3 (with Al). Sample 1078, grown at 250° C., has layers of film with and without Al, and alloying increases B:Hf from 3.4 to 4.1. This ratio is not the real film stoichiometry due to ionization and matrix effects in the SIMS measurement, but if the SIMS calibration does not vary with Al content (an assumption), then changes in the B:Hf ratio are approximately proportional to changes in the real film stoichiometry. The assumption is supported by Hf ion yield; when compared with RBS Hf incorporation, the SIMS Hf ion yield varies by no more than 2% between the HfB₂ and Hf₁₋ₓAlₓB_{y} film. With that consideration in mind, it may be concluded that the increase in B:Hf in the alloy relative to the pure HfB₂ supports the hypothesis that aluminum is capturing B in the film as AlBₓ. Preliminary data from scanning tunneling electron microscopy with energy dispersive spectroscopy indicate that B/Zr, which is analogous to B:Hf for the Zr₁₋ₓAlₓB_{y} system, also increases with alloying. It is noted that an increase in B/Hf or B/Hf during alloying is coupled to a decrease in the B/metal ratio.

### Effect on Crystallinity

Two routes may account for the improved crystallinity in this system: correcting B:metal stoichiometry and introducing an element with substantial surface diffusivity at growth temperatures. The argument for the first route starts from the background that diborane removal appearing to be kinetically limited during growth from Hf(BH₄)₄ alone, thus resulting in films that are overstoichiometric in B. Previous measurements of the B:Hf stoichiometry deem that HfB₂ is essentially stoichiometric, yet precision on those measurements is insufficient to rule out this case. Excess B is associated with grain refinement or amorphous phases in similar materials⁵²⁻⁵⁶. Further, it is postulated that adding Al pushes the B:metal stoichiometry towards the ideal 2:1, largely removing any stoichiometric imbalance.

The growth temperatures utilized correspond to homologous temperatures of 0.5-0.6 for aluminum, which is high enough to promote surface diffusion in elemental growth^{57, 58}. In contrast, the high melting temperature of HfB₂, 3280° C., corresponds to a very low homologous temperature and essentially no surface diffusion, assuming the absence of diffusion from any precursor intermediates. Presence of mobile Al may therefore help overcome the thermal barrier to crystallization in these films. A similar argument is used to show why CrB₂ films grown by pulsed laser deposition are amorphous at substrate temperatures below 500° C.; at 500° C., film crystallinity is attributed to growth at a Cr homologous temperature (0.35) sufficient for surface diffusion 59. Fortunately for the properties of the nanocrystalline Hf_{0.6}Al_{0.4}B_{y} films in this study, annealing to 700° C. exhibits no corrosion due to molten Al⁶⁰.

### Further Investigation on B Capture and Improved Crystallinity

To better understand this system, a kinetic model is outlined below using B coverage as the rate-limiting variable in this growth system; this model has been developed to describe the incorporation rate of Hf with and without TMAA addition. The overall result for incorporation rates from each alloy constituent (I_{HfB2}, I_{Al}),

$${I}_{HfB 2} = \frac{{k}_{r}^{B} + {F}_{Al}^{′}}{1 + \frac{{k}_{r}^{B}}{{F}_{Hf}^{′}}} and \qquad ( 4 )$$

$${I}_{Al} = {F}_{Al}^{′} , \qquad ( 5 )$$

agrees with experiments having surface rate-limited growth attributed to slow B removal (kᵣ^{B}) at high Hf(BH₄)₄ flux (F′_{Hf}) in the absence of TMAA, flux-limited Hf incorporation at fast surface reactions (kᵣ^{B}) to remove the excess B, and Hf incorporation governed by B coverage and TMAA flux (F′_{Al}) during alloy growth.

The present results may be extended to other refractory systems. To restate, the addition of boride forming metals in conjunction with metal boride precursors is proposed to promote the formation of stoichiometric, nanocrystalline films at low temperatures. The improved crystallinity at low temperatures alone is beneficial to advise low temperature processing for next-generation metallic interconnects in integrated electronics⁶¹⁻⁶³. This is a new case among other two-precursor CVD processes with remarkable kinetic effects, including growth inhibition^{35, 42, 64} and promotion⁶⁴⁻⁶⁸.

### Conclusions

This study explores the enhanced growth rates and microstructure from deposition of Hf₁₋ₓAlₓB_{y} films by low temperature chemical vapor deposition from two precursors. The correlation in Hf and Al incorporation rates indicates a strong interaction between the two precursors or their products, which affords increasing growth rates with increasing TMAA flux and a stable composition around x=0.40. At temperatures ≤250° C., total alloy growth rate is almost entirely controlled by the rate of Al incorporation in the film; increasing Hf(BH₄)₄ flux does not perturb growth rate or composition. Growth kinetics become more flux-limited at higher temperatures, so higher Hf concentrations can be obtained by increasing Hf(BH₄)₄ flux, although the enhancement in growth rate from Al incorporation persists. As-deposited alloy films are nanocrystalline, unlike pure HfB₂ films grown under similar conditions, and the microstructure indicates a solid solution of Hf₁₋ₓAlₓB₂ that implies the formation of Al—B bonds during growth. Alloy films have good step coverage in trenches with vertical sidewalls despite the enhanced growth rate from Al; the use of forward-directed fluxes yields thicker films along the flat trench bottom and top surfaces near the opening than on the sidewalls.

Fast growth rates and crystallinity can be attributed to Al consuming the excess B that is delivered to substrates as part of the HfB₂ precursor, Hf(BH₄)₄. These results suggest that, without Al at the surface, excess B is rate-limiting to HfB₂ growth due to the slow formation and removal of volatile borane products. Excess B in unalloyed films may also be instrumental in suppressing crystallization. In the alloy, however, Al can react with and incorporate B as AlB₂ for an overall reaction yielding only H₂ as the gaseous product. In general, co-flow of a second precursor, which delivers metal to act as a B sink, is a convenient route to enhancing growth rate and crystallinity in refractory borides without increasing the process temperature.

### References Corresponding to Example 1

1. H. K. M. AI-Jothery, T. M. B. Albarody, P. S. M. Yusoff, M. A. Abdullah and A. R. Hussein, IOP Conf. Ser.: Mater. Sci. Eng. 863 (1), 012003 (2020).
2. W. G. Fahrenholtz and G. E. Hilmas, Int. Mater. Rev. 57 (1), 61-72 (2012).
3. R. Kumar P, M. A. Hasan, A. Dey and B. Basu, J. Phys. Chem. C 125 (24), 13581-13589 (2021).
4. J. R. Shappirio, J. Vac. Sci. Technol. B 4 (6), 1409 (1986).
5. S. J. Deboer and H. N. AI-Shareef, U.S. Pat. No. 6,613,654 (2 Sep. 2003).
6. E. Kolawa, J. M. Molarius, W. Flick, C. W. Nieh, L. Tran and M.-A. Nicolet, Thin Solid Films 166, 29-35 (1988).
7. G. Sade and J. Pelleg, Appl. Surf. Sci. 91, 263-268 (1995).
8. G. C. Xing, C. M. Osburn and J. D. Hunn, J. Electrochem. Soc. 138, 3062 (1991).
9. D. J. Meschi, W. A. Chupka and J. Berkowitz, J. Chem. Phys. 33 (2), 530-533 (1960).
10. W. G. Fahrenholtz, G. E. Hilmas, I. G. Talmy and J. A. Zaykoski, J. Am. Ceram. Soc. 90 (5), 1347-1364 (2007).
11. C. Carney, T. Parthasarathy and M. K. Cinibulk, Int. J. Appl. Ceram. Technol. 10 (2), 293-300 (2013).
12. A. Rezaie, W. G. Fahrenholtz and G. E. Hilmas, J. Eur. Ceram. Soc. 27 (6), 2495-2501 (2007).
13. P. Hu, W. Guolin and Z. Wang, Corros. Sci. 51 (11), 2724-2732 (2009).
14. J. Zhao, H.-T. Liu, J.-X. Liu and G.-J. Zhang, Ceram. 40 (6), 8915-8920 (2014).
15. B. Mohammadpour, Z. Ahmadi, M. Shokouhimehr and M. Shahedi Asl, Ceram. 45 (4), 4262-4267 (2019).
16. E. P. Simonenko, N. P. Simonenko, I. A. Nagornov, V. G. Sevastyanov and N. T. Kuznetsov, Russ. J. Inorg. Chem. 65 (9), 1416-1423 (2020).
17. Y. Wang, L. Luo, J. Sun and L. An, Corros. Sci. 74, 154-158 (2013).
18. L. Weng, X. Zhang, W. Han and J. Han, Int. J. Refract. Hard Met. 27, 711-717 (2009).
19. A. Farhadizadeh, J. VIček, J. Houška, S. Haviar, R. Čerstvý and M. Červená, Ceram. Int. 48 (1), 540-547 (2022).
20. B. Bakhit, J. Palisaitis, J. Thörnberg, J. Rosen, P. O. Å. Persson, L. Hultman, I. Petrov, J. E. Greene and G. Greczynski, Acta Mater. 196, 677-689 (2020).
21. J. Fjellstedt, A. E. W. Jarfors and L. Svendsen, J. Alloys Compd 283, 192-197 (1999).
22. T. Fiantok, V. Šroba, N. Koutná, V. Izai, T. Roch, M. Truchlý, M. Vidiš, L. Satrapinskyy, Š. Nagy, B. Grančič, P. Kúš and M. Mikula, J. Vac. Sci. Technol. A 40 (3), 033414 (2022).
23. A. D. Pogrebnjak, A. A. Goncharov, A. N. Yunda, I. V. Shelest, V. V. Buranich, P. Konarski and P. Budzynski, Proc. 2017 IEEE 7th Int. Conf. Nanomater.: Appl. Prop. N. 2017, 01PCS136 (2017).
24. L. Tengdelius, M. Samuelsson, J. Jensen, J. Lu, L. Hultman, U. Forsberg, E. Janzén and H. Högberg, Thin Solid Films 550, 285-290 (2014).
25. G.-D. Sim, Y. S. Choi, D. Lee, K. H. Oh and J. J. Vlassak, Acta Mater. 113, 32-40 (2016).
26. Y. Cui, J. Y. Jeong, Y. Gao and S. G. Pyo, Micromachines 11, 32 (2020).
27. D. G. Coronell, E. W. Egan, T. Hamilton, A. Jain, R. Venkatraman and B. Weitzman, Thin Solid Films 333, 77-81 (1998).
28. A. M. Grishin, V. V. Putrolaynen and M. H. Yuzvyuk, Mater. Res. Express 4 (3), 036406 (2017).
29. E. Mohimi, O. T., S. Babar, A. A. Polycarpou and J. R. Abelson, Thin Solid Films 592, 182-188 (2015).
30. Y. Zhuk, Key Eng. Mater. 651-653, 467-472 (2015).
31. A. N. Cloud, “Ultraconformal chemical vapor deposition and synthesis of transition metal nitride films,” Ph.D. thesis, (University of Illinois at Urbana-Champaign, 2013).
32. N. Li, D. N. Ruzic and R. A. Powell, J. Vac. Sci. Technol. B 22 (6), 2734-2742 (2004).
33. S. Jayaraman, Y. Yang, D. Y. Kim, G. S. Girolami and J. R. Abelson, J. Vac. Sci. Technol. A 23 (6), 1619 (2005).
34. Y. Yang, S. Jayaraman, D. Y. Kim, G. S. Girolami and J. R. Abelson, Chem. Mater. 18, 5088 (2006).
35. K. L. Canova, Z. V. Zhang, G. S. Girolami and J. R. Abelson, J. Vac. Sci. Technol. A 39 (1), 013402 (2021).
36. K. B. Borisenko, A. J. Downs, H. E. Robertson, D. W. H. Rankin and C. Y. Tang, Dalton Trans., 967-970 (2004).
37. T. K. Talukdar, W. B. Wang, G. S. Girolami and J. R. Abelson, J. Vac. Sci. Technol. A 36 (5), 051513 (2018).
38. B. Bakhit, D. Primetzhofer, E. Pitthan, M. A. Sortica, E. Ntemou, J. Rosen, L. Hultman, I. Petrov and G. Greczynski, J. Vac. Sci. Technol. A 39 (6), 063408 (2021).
39. A. L. Wayda, L. F. Schneemeyer and R. L. Opila, Appl. Phys. Lett. 53 (5), 361-363 (1988).
40. O. A. Medvedeva, Sov. Powder Metall. 10 (8), 636 (1971).
41. E. J. Felten, J. Am. Chem. Soc. 78 (23), 5977-5978 (1956).
42. K. L. Canova, “Growth kinetics and microstructure in two precursor chemical vapor deposition of borides,” Ph.D. thesis, (University of Illinois Urbana-Champaign, 2022).
43. A. Yanguas-Gil, Y. Yang, N. Kumar and J. R. Abelson, J. Vac. Sci. Technol. A 27 (5), 1235-1243 (2009).
44. D. B. Beach, S. E. Blum and F. K. LeGoues, J. Vac. Sci. Technol. A 7 (5), 3117-3118 (1989).
45. O. P. Korobeinichev, A. G. Shmakov, A. A. Chernov, M. L. Kosinova, V. S. Sulyaeva and F. A. Kuznetsov, Inorg. Mater. 47 (11), 1199-1204 (2011).
46. G. E. Moore and F. C. Unterwald, J. Chem. Phys. 40 (9), 2639-2652 (1964).
47. L. H. Long, J. Inorg. Nucl. Chem. 32, 1097-1115 (1970).
48. J. Sung, D. M. Goedde, G. S. Girolami and J. R. Abelson, J. Appl. Phys. 91 (6), 3904-3911 (2002).
49. T. Matsuda and H. Kawashima, J. Catal. 49, 141-149 (1977).
50. H. I. Schlesinger, R. T. Sanderson and A. B. Burg, J. Am. Chem. Soc. 62 (12), 3421-3425 (1940).
51. N. Kumar, Y. Yang, W. Noh, G. S. Girolami and J. R. Abelson, Chem. Mater. 19, 3802-3807 (2007).
52. W.-J. Liu, Y.-H. Chang, C.-L. Fern, Y.-T. Chen, B.-J. Huang, S.-T. Hsu, S.-H. Lin, T.-H. Wu, P.-W. Chi and K.-W. Lin, Optik 259, 168985 (2022).
53. T. Santos and N. Smith, U.S. Pat. No. 11,031,058 (8 Jun. 2021).
54. S. Tamirisakandala, R. B. Bhat, J. S. Tiley and D. B. Miracle, Scr. Mater. 53 (12), 1421-1426 (2005).
55. T. T. Cheng, Intermetallics 8, 29-37 (2000).
56. J. S. Kim, G. Kim, J. Jung, K. Jung, J. Cho, W. Y. Kim and C. Y. You, Sci Rep 12 (1), 4549 (2022).
57. J. A. Thornton, J. Vac. Sci. Technol. A 4 (6), 3059-3065 (1986).
58. B. A. Movchan and A. V. Demchishin, Fiz. Metal. Metalloved. 28, 653-660 (1969).
59. A. De Bonis, A. Galasso, A. Latini, J. V. Rau, A. Santagata, M. Curcio and R. Teghil, Coatings 9 (12), 777 (2019).
60. S. Shrivastav, D. Yun, C. Romnes, K. L. Canova, J. R. Abelson and J. A. Krogstad, (In preparation).
61. D. Gall, J. J. Cha, Z. Chen, H.-J. Han, C. Hinkle, J. A. Robinson, R. Sundararaman and R. Torsi, MRS Bulletin 46, 959-966 (2021).
62. N. A. Lanzillo, J. Appl. Phys. 121 (17), 175104 (2017).
63. N. A. Lanzillo and D. C. Edelstein, J. Vac. Sci. Technol. B 40 (5), 052801 (2022).
64. E. C. Stassinos and H. H. Lee, J. Appl. Phys. 60 (11), 3905-3909 (1986).
65. B. S. Meyerson, K. J. Uram and F. K. LeGoues, Appl. Phys. Lett. 53 (25), 2555-2557 (1988).
66. P. M. Garone, J. C. Sturm, P. V. Schwartz, S. A. Schwarz and B. J. Wilkens, Appl. Phys. Lett. 56 (13), 1275-1277 (1990).
67. P. D. Agnello, T. O. Sedgwick and J. Cotte, J. Electrochem. Soc. 140 (9), 2703-2709 (1993).
68. Y. Yang, “Chemical vapor deposition of metal diboride and metal oxide thin films from borohydride-bonded precursors,” Ph.D. thesis, (University of Illinois at Urbana-Champaign, 2007).

### Example 2: Growth of Ti₁₋ₓAlₓB_{y} Using Ti(BH₄)₃(Dme) with TMAA

In order to support the hypothesis that Al acts as a B sink for extra BH₄ groups on the substrate brought by the other precursor, TMAA was co-flowed with a precursor similar to Hf(BH₄)₄, Ti(BH₄)₃(dme) (dme: 1,2-dimethoxyethane) [29]. If Al reacts with BH₄ groups to form AlB₂, then the predicted stoichiometry of alloy films would be 2:1 Ti:Al. This would occur under the condition that TiB₂ deposition from Ti(BH₄)₃(dme) is surface reaction rate limited, similar to Hf(BH₄)₄, but these experiments are unable to confirm this point.

Ti(BH₄)₃(dme) is not as volatile as other precursors, TMAA and HfBH, in this study, so the precursor reservoir and delivery lines were heated to 50° C. Under these conditions, the chamber manometer sees a spike in total pressure of about 0.02 mTorr when the precursor valve is opened, and then the pressure returns to its original value. To avoid saturating the growth in Al with co-flow of TMAA, this precursor's flux is maintained at a low value which is also below the detection limit for the manometer. Steady-state growth in these experiments confirm that the substrates continue to receive precursor flux even if a pressure rise cannot be measured, but the relative precursor fluxes are unknown.

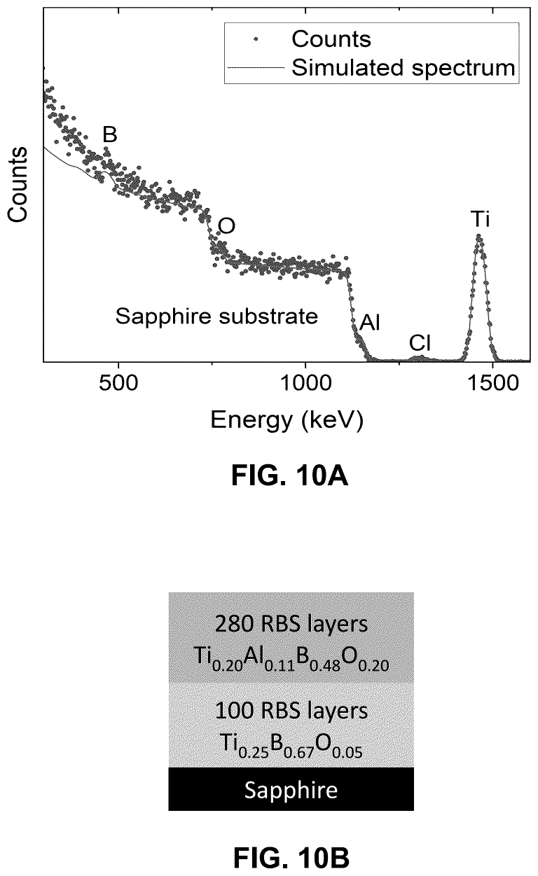

Two experiments grew alloy films. The first used c-plane sapphire as substrate and heated the substrate to 225° C. Nucleation was not observed from Ti(BH₄)₃(dme) at 200° C., unlike growth reported in literature; changes in nucleation may be due to differences in substrate preparation and precursor flux. No nucleation was observed for the first few minutes of Ti(BH₄)₃(dme) flow alone. Upon adding a small flow of TMAA, film growth began rapidly, and growth continued after the TMAA source was shut off. Growth of TiB₂ continued for 15 minutes. The TMAA source was opened again, and alloy was grown for the 20 following minutes. FIG. 10A shows the RBS compositional profile of this film; despite the fact that no pressures were measured by the manometer, alloy film grew at a fair rate of about 1 nm min⁻¹ (roughly estimated from the number of atomic layers in RBS fitting having 10¹⁵ atoms cm⁻²). The alloy film matches the metal stoichiometry predicted by Al consumption of excess BH₄ ligands.

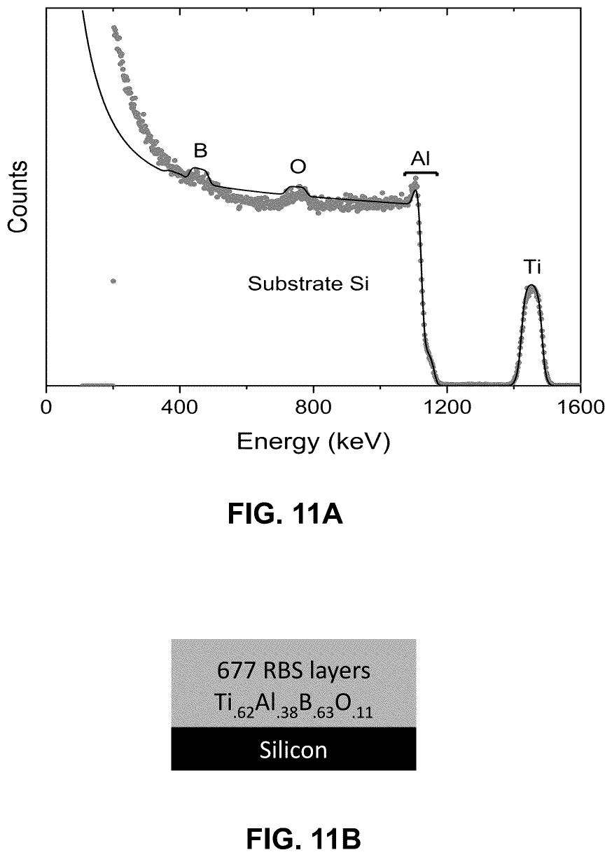

After observing the TMAA-induced nucleation at 225° C., the second experiment grew film on a Si substrate at 200° C. (FIG. 11A). The main motivation for this change was to lower deposition temperature, as C and O contamination is observed in films grown between 20° and 300° C. due to decomposition of the dme ligand. In fact, the film appears to be more contaminated with O than the film grown at higher temperature; about 11% of the film composition in the RBS fit is attributable to O. It is not certain whether oxidation occurred during or after deposition or why this film appears to be much more contaminated than the one grown at 225° C. Diffraction of this film shows no evidence of crystallinity, which may be suppressed by film impurities.

### Example 3: Post-Deposition Heat Treatment

In some embodiments, after the diboride alloy coating is formed as described above, the coating may be heat treated. The heat treatment step may serve to improve hardness and/or crystallinity of the coating. For example, a Hf₁₋ₓAlₓB_{y} coating was applied to a silicon substrate. Then, the coated substrate was placed in a crucible with a silicon chip covering the coating as an oxygen scavenger to prevent oxidation of the surface of the diboride alloy coating. The crucible may then be heated under nitrogen. In one experiment, a coated substrate was heat treated at a temperature of 700° C. In a second experiment, a coated substrate was heat treated at a temperature of 900° C. Both samples showed improved crystallinity and hardness.

Furthermore, the as-deposited samples showed compositional gradients through the depth of the diboride alloy coating with respect to B, Hf and Al. For the sample heat treated at 700° C., the compositional gradient was reduced, particularly for B and Al for each of the. For the sample heat treated at 900° C., aluminum began to diffuse out toward the surface of the coating, particularly in the first ˜80 nm of depth. In some embodiments, the out diffusion of Aluminum may be beneficial for oxidation resistance, provided the coatings are sufficiently thick.

### Example 4: Characterization of the Diboride Alloy Coatings

The as-deposited film compositions were measured ex-situ using Rutherford backscattering spectrometry (RBS, NEC Pelletron accelerator) and fit to layered compositional profiles using Simnra software. Initial surface morphology and film thickness were observed using scanning electron microscopy (Scios2-Dual beam SEM/FIB) and Transmission Electron Microscopy (JEOL 2010 LaB6) respectively. Surface roughness was measured using Atomic Force Microscopy (Asylum Research MFP-3D AFM), in the tapping mode. Following this initial characterization, the specimens were diced into smaller pieces to allow for various thermal exposures of the same thin film.

All heat treatments were performed in a thermogravimetric analyzer (Q50-TGA). The heating and cooling rates were always fixed at 10° C./min and 50° C./min, respectively, but different maximum temperatures and annealing environments were used. Maximum temperatures of 700, 800 and 900° C. were targeted under nitrogen atmospheres (where the primary impurity was oxygen) or air. Hold times at these maximum temperatures range from 0 minutes (no dwell) to 60 minutes.

Film morphology was again characterized via SEM following heat treatments. The films were coated with a protective gold palladium (Au—Pd) film via DC magnetron sputtering. This reduced charging during SEM observations. Cross-sectional characterization of the heat-treated specimens was performed by extracting lamella via focused ion beam milling (Scios2-Dual beam SEM/FIB) and observation via (scanning) transmission electron microscopy, TEM, (JEOL 2010 LaB6, 200 kV and FEI Themis-Z, 300 kV. Oxidation products formed during the heat treatments were identified using selected area electron diffraction, SAED, (JEOL 2010 LaB6, 200 kV). And any changes in film composition due to heat treatments were measured using energy dispersive 10 spectroscopy (EDS, FEI Themis-Z, 300 kV, 0.35-0.4 nA). Each spectrum was collected for 15-30 minutes using a 50-70 μm C2 aperture.

Properties of as-Deposited Hf₁₋ₓAlₓB_{y} Films and HfB_{y} Films

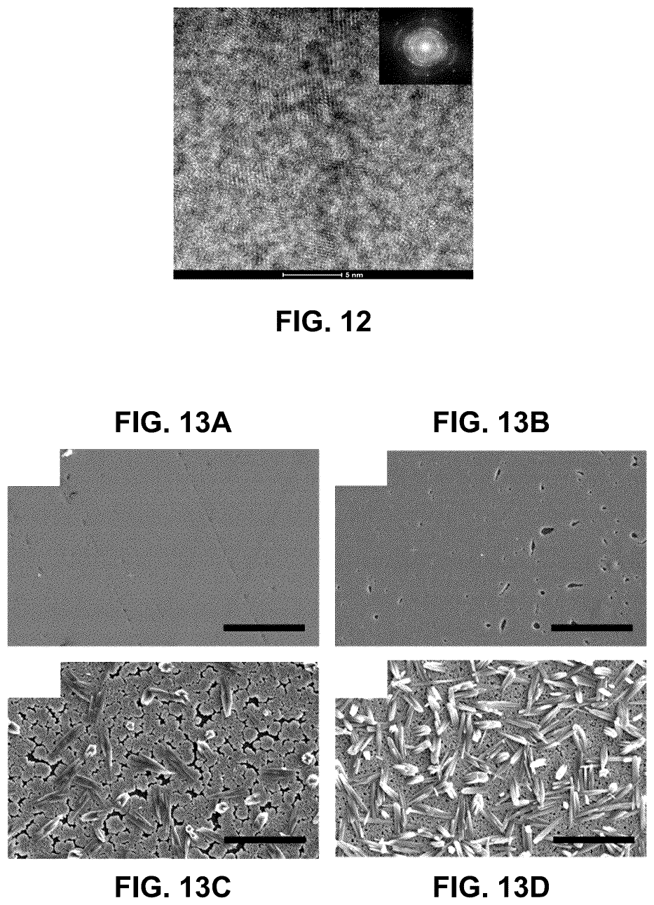

The surface of the as-deposited films is relatively flat and even (FIGS. 13A-13D), with a surface roughness of ˜1.3 nm, measured using AFM. Some voids in the as-deposited film are visible in FIG. 13A, and these may be attributed to contaminants on the substrate that produced unreactive surface defects. TEM cross sections reveal the presence of a thin native oxide layer (Error! Reference source not found. 14A-14C) that is between 2-5 nanometers in thickness. Film composition was measured by STEM EDS and RBS and is reported in terms of Al/Hf ratio in Table 3. For convenience the three thin films are labeled according to their increasing Al content. Coating A corresponds to the unalloyed HfB_{y} specimens. Coating B is alloyed with a moderate amount of Al that does not exceed the Hf content: Hf_{0.62}Al_{0.38}B_{y}. Finally, Coating C contains an excess of Al relative to Hf: Hf_{0.25}Al_{0.75}B_{y}. Both Coating A and B are chemically homogenous over the cross-section, with no perceptible evidence of elemental segregation, while Coating C exhibits a mild compositional gradient, with aluminum content decreasing from an average of 33 at % Al near to substrate to ˜28 at % Al near the surface. There are also heterogeneous aluminum-rich pockets near the substrate in Coating C. Notably, Coating B presents evidence of nanocrystallinity, FIG. 12.

TABLE 3
List of coatings with respective composition,
thickness, and heat treatment

| Coating | Al/Hf | Thickness | Heat treatment |
|---|---|---|---|
| A | 0 | 100 nm | 700° C., Air |
| B | 0.61 | 50 nm | 700° C., 800° C., 900° C. in N₂ |
| C | −3 | 100 nm | 700° C., Air |

Turning now to FIGS. 13A-13D, plan-view SEM images of the ˜50 nm thick Hf_{0.62}Al_{0.38}B_{y} film (Coating B) grown on sapphire (FIG. 13A) as-deposited and annealed to (FIG. 13B) 700, (FIG. 13C) 800, and (FIG. 13D) 900° C. are shown. No significant change in morphology is observed up to 700° C., but small nuclei and needles of aluminum borate are visible on the surface of the film heated to 800° C. Here, some cracking can also be seen. (FIG. 13D) For films heated to 900° C., well defined and faceted aluminum borate needles are spread on the sample surface. The scale bar is 3 μm and is the same for all images.

Evolution of Composition and Microstructure of Hf_{0.62}Al_{0.38}B_{y} Coatings (Coating B) with Temperature

Annealing experiments between 70° and 900° C. performed in a nitrogen atmosphere with no dwell were initially used to investigate the temperature range over which Coating B transitioned from gradual and uniform oxidation to complete consumption of the thin film. Moisture is the main impurity in the nitrogen environment.

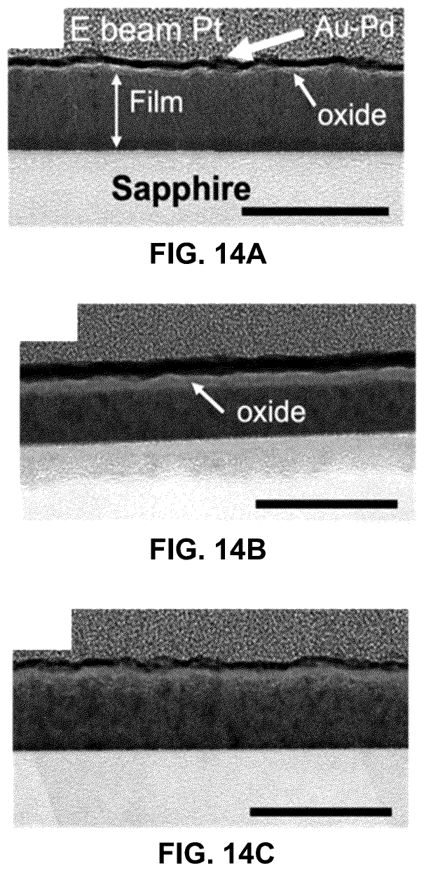

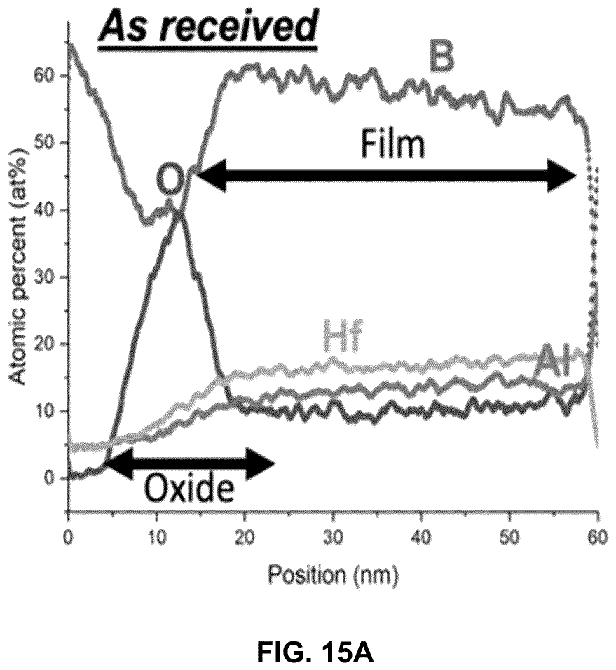

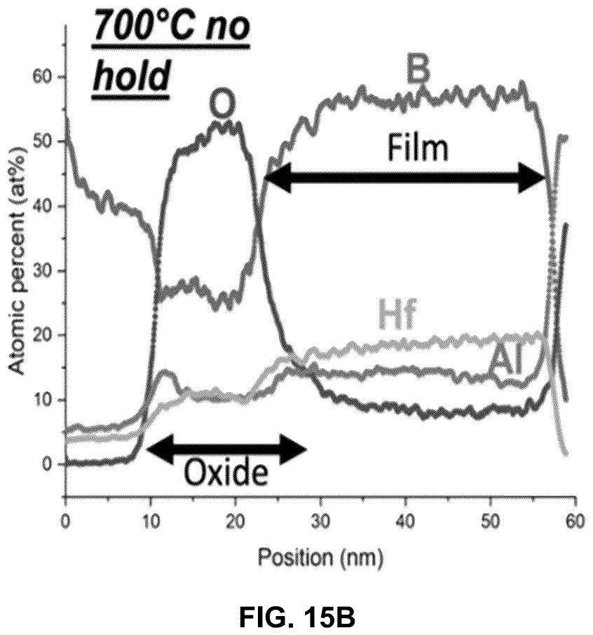

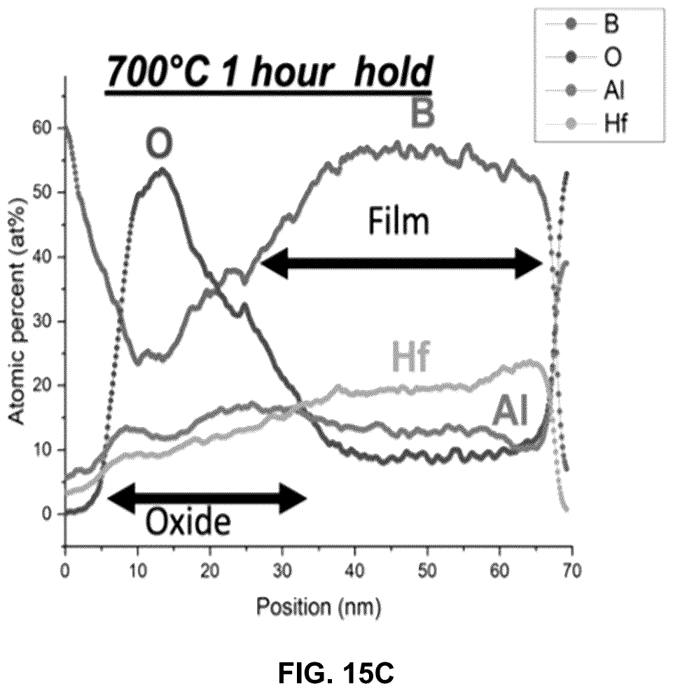

The surface remained smooth following the heat treatment to 700° C., as illustrated in FIG. 13B. Closer inspection of the cross section via TEM analysis reveals growth of the oxide layer up to 10 nm relative to the native oxide on the as-deposited films (˜4-5 nm), both of which are imaged in FIGS. 14A-14C. This oxide layer appears to be amorphous, based on STEM-HAADF images. There are no evident cracks visible in the cross section of the film after heating to 700° C. High resolution HAADF images show little to no crystallite growth in the films relative to the as-deposited microstructure, though the crystallites appear to be more defined. Using STEM-EDS, it was found that the films annealed to 700° C. have little to no chemical segregation and are compositionally homogeneous (FIGS. 15A-15C). The uniform oxide formed on the film surface is composed of two layers, the outermost layer of oxide is rich in aluminum, while the oxide closer to the film is rich in hafnium (FIGS. 15A-15C).

Turning now to FIGS. 14A-14C, cross-sectional TEM shows the effect of annealing on oxidation for (FIG. 14A) the as-deposited film B, (FIG. 14B) film B annealed to 700° C., and (FIG. 14C) film B annealed to 700° C. with an isothermal hold for one hour. The film in FIG. 14A is 51-53 nm thick with a thin surface oxide. The film after annealing shows a thicker surface oxide, which does not change significantly in thickness after holding for one hour. After annealing, the film is 52-55 nm thick with about˜10 nm of surface oxide. The scale is 100 nm and is the same for all images.

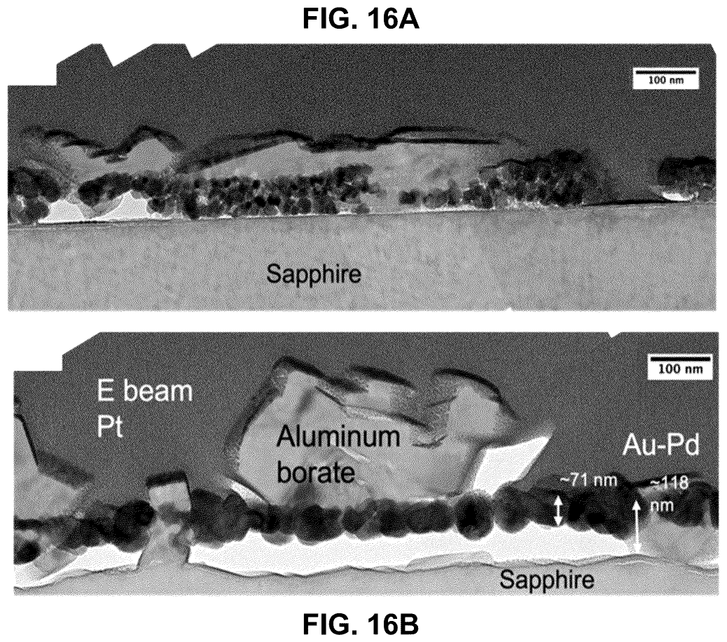

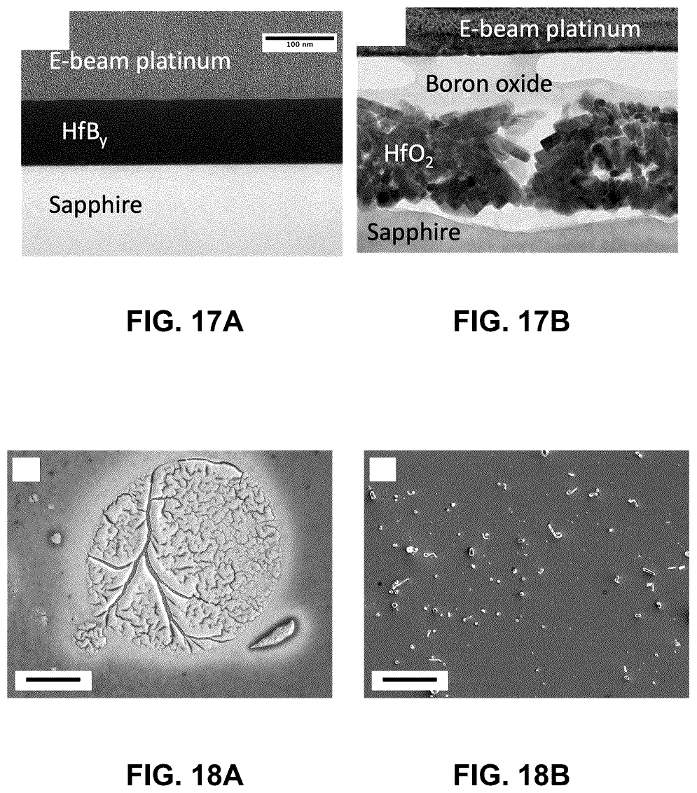

The specimen from Coating B that was heated to 800° C. (shown in Error! Reference source not found.3 C) exhibited increased surface roughness relative to the same coating heat treated to 700° C. This increased roughness was largely the consequence of small acicular, highly faceted features uniformly distributed across the surface. Cracking of the film between these acicular features was also observed. It is evident from the cross-sectional TEM micrographs presented in FIG. 16A, that these needle-like features span the original thickness of the film and the continuous oxide layer observed at 700° C. is not present. The finer, equiaxed features in darker contrast near the sapphire substrate are rich in hafnium and oxygen, while the acicular features are predominantly aluminum, boron and oxygen. No evidence was found for unoxidized regions within the films heat treated to 800° C.

Another specimen from Coating B was heated to 900° C. in a nitrogen environment with similar results. The rough surface morphology was defined by even longer and more clearly faceted acicular features as shown in Error! Reference source not found. Relative to the 800° C. sample, this sample had an increased areal density and length of the needles, and there were only a limited number of cracks on the film surface. TEM cross sections show the needles of aluminum borate growing out of the sapphire substrate with crystallites of hafnium oxide (both compounds identified from stoichiometry using EDS) embedded within the needles (FIG. 16B). No continuous oxide layer is present in the cross section of this sample. In some regions, corrosion of the sapphire substrate is evident, with a gap visible between the layer of hafnium oxide and sapphire substrate. Selected area diffraction patterns from the 900° C. coating, confirm that the features are monoclinic Al₄B₂O₉[31]. This also suggests that the features in the 800° C. coatings could be an initial form of aluminum borate, Al₄B₂O₉, which is known to have an acicular/whisker like morphology [25,26]. Aluminum borate is a reaction product of aluminum oxide and boron oxide, with boron oxide being a necessary reactant. Evidence for this includes another sample from Coating B that was heat treated in nitrogen to 900° C., but with the addition of a silicon chip to act as an oxygen getter. No aluminum borate needles were visible, and the cross section shows the presence of a uniform, albeit rough, oxide layer. For this sample, enough boron oxide may not have formed to react and produce aluminum borate.

### Phase and Microstructural Evolution During Extended Isothermal Heat Treatments at 700° c. (Coatings A, B And C)

Specimens from Coating B did not fully oxidize when heat treated to 700° C. with no dwell. Another sample taken from Coating B was thus subjected to an extended treatment of 1 hour at 700° C. in a nitrogen environment to observe changes in the oxygen content of the film, composition changes in the oxide scale, and/or changes in thickness of this oxide layer. No qualitative differences in surface morphology of the films were found (FIGS. 13A-13D). The oxide thickness in films held at 700° C. for 1 hour was similar to those heat treated without a dwell to 700° C. Some compositional segregation was observed within the unoxidized portions of the film after the isothermal hold. Such segregation was limited to regions of the film near the oxide interface as shown in FIGS. 15A-15C. This region of the film near the oxide scale interface shows evidence of deeper oxygen ingress that was not observed for shorter heat treatments. However, the overall oxygen concentration away from this interface remains at an average of 10 at. % or less for the samples in the as-deposited, annealed to 700° C., and annealed to 700° C. with a one-hour hold conditions.

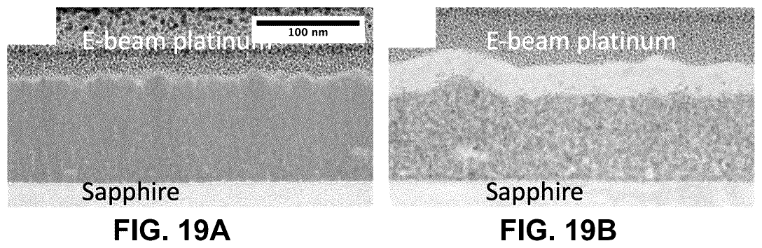

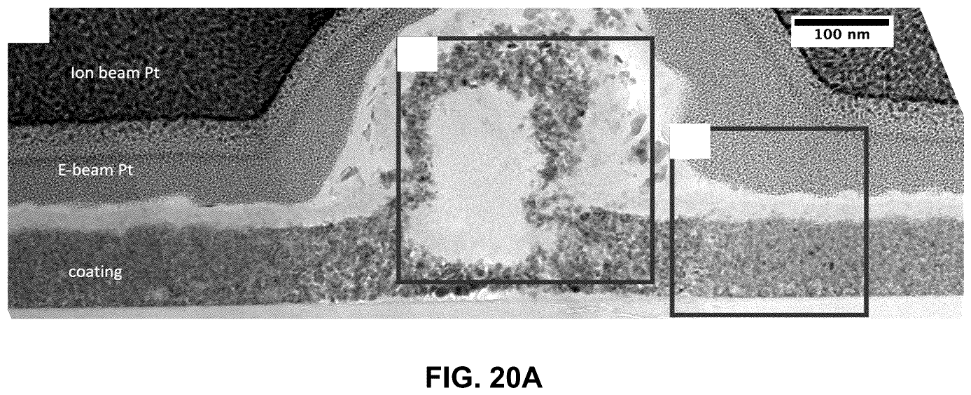

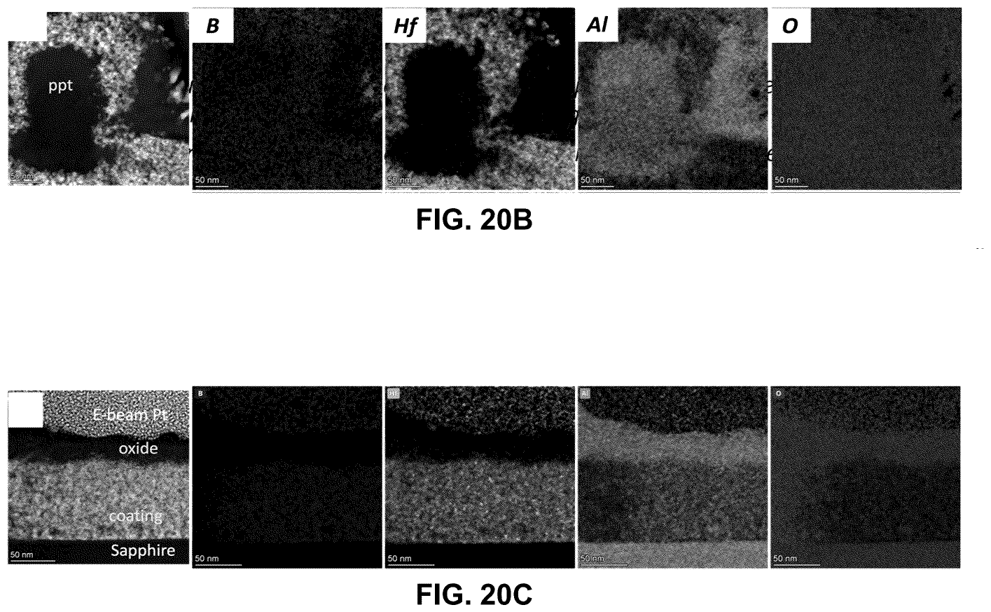

Coatings A and C, were subjected to the same extended heat treatment of 1 hour at 700° C., but these experiments were performed in air rather than nitrogen. The unalloyed coating completely oxidized resulting in hafnium oxide crystallites embedded in a boron oxide matrix (Error! Reference source not found.). Significant surface cracking following oxidation was observed, as shown in FIGS. 18A-18B. The thickness of the coating also increased. And, much like the results presented for Coating B at 900° C., regions of the sapphire substrate are etched. In comparison, the coating with excess aluminum, Coating C, forms a uniform, 30 nm thick oxide which is rich in aluminum (FIG. 19B). The surface of the Coating C specimen does not exhibit an apparent cracking, but FIG. 19B does reveal some spherical and nodular features distributed across the surface. The TEM cross section from a region including such a nodular feature is presented in FIGS. 20A-20C. These nodules consist of nanocrystalline Al₄B₂O₉, which was identified using nanobeam electron diffraction, NBED. The coating around the nodule was nearly or completely oxidized, with the NBED collected in these regions including peaks from hafnium oxide. Regions of the coating away from the nodular feature, however, show a diboride structure with no oxide peaks. Finally, the sapphire interface does not present any visible evidence for dissolution or etching.

### Discussion

The addition of solid solution aluminum to hafnium diboride thin films clearly increases the durability of the films subjected to elevated temperatures and oxidizing conditions. Specifically, aluminum has the potential (i) to reduce or eliminate crystallization induced cracking that is observed in unalloyed thin films, and (ii) to form a continuous protective oxide scale that limits inward oxygen transport and further oxidation. However, these improvements are not without caveat, and it is critical that the ratio of Al:Hf not be overlooked.

The oxide film that is established on Coating B at 700° C. is effectively protective but cannot be considered truly passivating. Increasing time at 700° C. resulted in a negligible change in oxide thickness. Yet the oxygen concentration profile beyond the apparent oxide interface evolves over the same time, as does the aluminum profile. As oxygen diffuses inward, aluminum diffuses towards the oxide interface and into the oxide, as depicted in FIGS. 15A-15C. This is explained by the difference in oxygen affinities of hafnium, aluminum, and boron, with boron and aluminum more likely to respond to gradients in oxygen activity than hafnium. This evidence of Al mobility within the diboride matrix is notable and perhaps surprising given the paucity of diffusivity values for most transition metal diborides in the literature and the homologous temperature of these experiments. While the crystallite size is too small to completely eliminate the possibility of grain boundary enrichment and diffusion, no apparent phase separation was found. This is further corroborated by the lack of evidence for any phase segregation, in coating B that was heat treated to 900° C. in nitrogen with a silicon chip for gettering oxygen.

At first glance, formation of large, highly faceted crystals of the aluminoborate (Al₄B₂O₉) phase at higher temperatures suggests a functional upper limit for the use of aluminum hafnium borides films and coatings in an oxidizing environment. The needle-like morphology would preclude the aluminoborate phase from forming a continuous, protective oxide layer. However, upon closer inspection it became evident that formation of this phase was a direct consequence of initial breaches in the film. Such initial defects allowed for rapid oxidation of boron and aluminum and subsequent reaction of these oxides. This was confirmed by two key observations. The first of these was the increased roughness of the sapphire substrate for the fully oxidized Coating A. Even though there is no Al in the film to begin with, once the boron has oxidized, it can attack the sapphire (Al₂O₃) substrate. No direct evidence of the crystalline aluminoborate phase was observed under these conditions, but nucleation of this phase is expected to be kinetically limited below approximately 750° C.[25-27]. The second key observation was the formation of a continuous oxide layer at 900° C. when the oxygen partial pressure was further reduced by gettering with a nearby uncoated Si wafer. By reducing the driving force for oxidation under these conditions, the rapid oxidation of boron near defects could be suppressed and demonstrated that a stable, continuous oxide could form at temperatures above 750° C. if the oxidation of boron is limited. This insight provides some additional flexibility regarding the suitable operating conditions under which aluminum, hafnium boride films and coatings could be applicable.

However, formation of this deleterious aluminum borate phase is expected for any diboride films (e.g, TiB₂, ZrB₂, or CrB₂) alloyed with aluminum, since all diborides have a common mechanism for oxidation resistance. Thus, further efforts to improve oxidation resistance of diborides for applications at temperatures greater than 800° C., may require consideration of other alloying elements that form a protective oxide that does not react with boron oxide. Furthermore, improved surface preparation is expected to significantly suppress the initiating defects that lead to the rapid formation of aluminoborate at temperatures above 750° C.

The addition of aluminum afforded favorable changes in the initial microstructure and its stability at elevated temperatures and oxidizing conditions. It might be intuitive to further increase the aluminum concentration in an effort to enhance the stability of the protective oxide scale and decrease the rate of inward oxygen diffusion. However, careful inspection of Coating C, wherein the Al:Hf>1, as shown in Table 3, suggests that there may be a fundamental limit to the solubility of aluminum within the host hafnium diboride structure. As of yet, it is not clear if this limit is a thermodynamic limit or one imposed by the nature of the thin film growth mechanism, but regardless of the root cause, Coating C contained notable and persistent pockets that were rich in aluminum. For most of the coating surface, the overall oxidation behavior of Coating C mirrored that of Coating B—forming a continuous and dense oxide layer at 700° C. Yet, as depicted in FIGS. 20A-20C, the formation of Al-rich nodules disrupts this protective coating, causing neighboring regions of the coating to become fully oxidized. Current evidence is insufficient to determine whether these nodules are the result of defects in the initial films or the consequence of coalescence of many smaller Al-rich domains during heat treatment. But regardless of their source, expansion of such large, Al-rich domains as they melt has caused the protective oxide to rupture and allowed for rapid oxidation. Such oxidization seems to have formed enough aluminia and boria to react and form aluminum borate. Whether driven by the aluminum borate, or simply the strong gradient in oxygen activity, leaching of aluminum and some boron from the nearby film was observed (FIGS. 20A-20C). Such leaching was not limited to the Al-rich intergranular regions, but also caused migration of the aluminum that was in solution within the hafnium boride structure. This, along with the disappearance of the composition gradient in Coating C after heat treatment, is yet another example of the mobility of aluminum within this structure, given a strong enough driving force. Taken together, these observations have demonstrated that increasing the aluminum concentration above a certain threshold was not an effective strategy to completely suppress the rate of oxidation and thereby the formation of aluminum borate.

Thus, under the right conditions the addition of aluminum did have a beneficial effect in slowing the rate of oxidation. Coatings alloyed with aluminum may be useful at temperatures lower than 700° C., or under conditions in which the oxygen partial pressure is sufficiently low. Aluminum not only led to the formation of a protective aluminum rich oxide, but also improved the overall mechanical integrity of the films by imparting nanocrystallinity in the as-deposited state, thereby suppressing crystallization cracks.

### Conclusion

Hf₁₋ₓAlₓB_{y} coatings are shown to have promising oxidation behavior at 700° C., with the addition of aluminum providing the beneficial effect of forming a continuous, protective Al-rich oxide scale that slowed the rate of oxidation and inward diffusion of oxygen. When compared to unalloyed HfB_{y} coatings, which completely oxidized under the same conditions and experienced substantial cracking, the addition of aluminum prevented cracking during heat treatment. The reason behind this improvement was either the nanocrystalline nature of the as-deposited film (Al:Hf=0.61) or that the film readily accommodated crystallization due to the presence of many Al-rich intergranular pockets (Al:Hf>2). Unfortunately, at temperatures above 700° C. or in films with an excess of aluminum, a nonprotective aluminum borate phase was frequently observed.

And while this phase could be suppressed by reducing the oxygen partial pressure or eliminating surface defects in the as-deposited films, it is likely that application of such thin films at higher temperatures will require exploration of alternative alloy chemistries.

### REFERENCES FOR EXAMPLE 4

(1) Fahrenholtz, W. G.; Hilmas, G. E.; Talmy, I. G.; Zaykoski, J. A. Refractory Diborides of Zirconium and Hafnium. J. Am. Ceram. Soc. 2007, 90 (5), 1347-1364.
(2) Tului, M.; Ruffini, F.; Arezzo, F.; Lasisz, S.; Znamirowski, Z.; Pawlowski, L. Some Properties of Atmospheric Air and Inert Gas High-Pressure Plasma Sprayed ZrB2 Coatings. Surf. Coat. Technol. 2002, 151, 483-489.
(3) Agarwal, A.; Dahotre, N. B. Comparative Wear in Titanium Diboride Coatings on Steel Using High Energy Density Processes. Wear 2000, 240 (1-2), 144-151.
(4) Sonber, J.; Raju, K.; Murthy, T. C.; Sairam, K.; Nagaraj, A.; Majumdar, S.; Kain, V. Friction and Wear Properties of Zirconium Diboride in Sliding against WC Ball. Int. J. Refract. Met. Hard Mater. 2018, 76, 41-48.
(5) Chatterjee, A.; Jayaraman, S.; Gerbi, J.; Kumar, N.; Abelson, J.; Bellon, P.; Polycarpou, A.; Chevalier, J. Tribological Behavior of Hafnium Diboride Thin Films. Surf. Coat. Technol. 2006, 201 (7), 4317-4322.
(6) Yadav, K. K.; Guchhait, S. K.; Hussain, C.; Ganguli, A. K.; Jha, M. Synthesis of Zirconium Diboride and Its Application in the Protection of Stainless Steel Surface in Harsh Environment. J. Solid State Electrochem. 2019, 23, 3243-3253.
(7) Wang, Q.; Wang, W. J.; Liu, H. J.; Zeng, C. L. Corrosion Behavior of Zirconium Diboride Coated Stainless Steel in Molten 6061 Aluminum Alloy. Surf. Coat. Technol. 2017, 313, 129-135.
(8) Magnuson, M.; Hultman, L.; Högberg, H. Review of Transition-Metal Diboride Thin Films. Vacuum 2022, 196, 110567.
(9) Fahrenholtz, W.; Hilmas, G. Oxidation of Ultra-High Temperature Transition Metal Diboride Ceramics. Int. Mater. Rev. 2012, 57(1), 61-72.
(10) Irving, R.; Worsley, I. The Oxidation of Titanium Diboride and Zirconium Diboride at High Temperatures. J. Common Met. 1968, 16 (2), 103-112.
(11) Litz, L. M.; Mercuri, R. Oxidation of Boron Carbide by Air, Water, and Air-Water Mixtures at Elevated Temperatures. J. Electrochem. Soc. 1963, 110 (8), 921.
(12) Naraparaju, R.; Maniya, K.; Murchie, A.; Fahrenholtz, W. G.; Hilmas, G. E. Effect of Moisture on the Oxidation Behavior of ZrB2. J. Am. Ceram. Soc. 2021, 104 (2), 1058-1066.
(13) Mattia, D.; Desmaison-Brut, M.; Dimovski, S.; Gogotsi, Y.; Desmaison, J. Oxidation Behaviour of an Aluminium Nitride-Hafnium Diboride Ceramic Composite. J. Eur. Ceram. Soc. 2005, 25 (10), 1789-1796.
(14) Rezaie, A.; Fahrenholtz, W. G.; Hilmas, G. E. Evolution of Structure during the Oxidation of Zirconium Diboride-Silicon Carbide in Air up to 1500° C. J. Eur. Ceram. Soc. 2007, 27 (6), 2495-2501.
(15) Hu, P.; Guolin, W.; Wang, Z. Oxidation Mechanism and Resistance of ZrB2-SiC Composites. Corros. Sci. 2009, 51 (11), 2724-2732.
(16) Wang, Y.; Luo, L.; Sun, J.; An, L. ZrB2-SiC (AI) Ceramics with High Resistance to Oxidation at 1500° C. Corros. Sci. 2013, 74, 154-158.
(17) Bakhit, B.; Palisaitis, J.; Thörnberg, J.; Rosen, J.; Persson, P. O.; Hultman, L.; Petrov, I.; Greene, J. E.; Greczynski, G. Improving the High-Temperature Oxidation Resistance of TiB2 Thin Films by Alloying with Al. Acta Mater. 2020, 196, 677-689.
(18) Fiantok, T.; Šroba, V.; Koutná, N.; Izai, V.; Roch, T.; Truchl\grave{y}, M.; Vidiš, M.; Satrapinskyy, L.; Nagy, Š.; Grančič, B.; others. Structure Evolution and Mechanical Properties of Co-Sputtered Zr-Al-B2 Thin Films. J. Vac. Sci. Technol. Vac. Surf. Films 2022, 40 (3), 033414.
(19) Canova, K. L.; Shrivastav, S.; Caroff, C. M.; Souqui, L.; Krogstad, J. A.; Girolami, G. S.; Abelson, J. R. Role of Al in Enhancing Growth Rate and Crystallinity in Low Temperature Chemical Vapor Deposition of Hf1-xAlxBy Thin Films.
(20) Jayaraman, S.; Yang, Y.; Kim, D. Y.; Girolami, G. S.; Abelson, J. R. Hafnium Diboride Thin Films by Chemical Vapor Deposition from a Single Source Precursor. J. Vac. Sci. Technol. Vac. Surf. Films 2005, 23 (6), 1619-1625.
(21) Sung, J.; Goedde, D. M.; Girolami, G. S.; Abelson, J. R. Remote-Plasma Chemical Vapor Deposition of Conformal ZrB 2 Films at Low Temperature: A Promising Diffusion Barrier for Ultralarge Scale Integrated Electronics. J. Appl. Phys. 2002, 91 (6), 3904-3911.
(22) Kumar, N.; Yang, Y.; Noh, W.; Girolami, G. S.; Abelson, J. R. Titanium Diboride Thin Films by Low-Temperature Chemical Vapor Deposition from the Single Source Precursor Ti (BH₄) 3 (1, 2-Dimethoxyethane). Chem. Mater. 2007, 19 (15), 3802-3807.
(23) Gielisse, P.; Foster, W. The System Al2O3-B2O3. Nature 1962, 195 (4836), 69-70.
(24) Baldridge, T.; Gupta, M. C.; Sun, C.-N. Nanostructures from Zirconium Diboride and Alumina Ceramics. J. Am. Ceram. Soc. 2010, 93 (9), 2891-2896.
(25) Hernández, M. F.; Suárez, G.; Cipollone, M.; Conconi, M. S.; Aglietti, E. F.; Rendtorff, N. M. Formation, Microstructure and Properties of Aluminum Borate Ceramics Obtained from Alumina and Boric Acid. Ceram. Int. 2017, 43 (2), 2188-2195.
(26) Luo, H.; Li, Y.; Xiang, R.; Li, S.; Xu, N.; Chen, R.; Jia, W. Microstructural Evolution and Kinetics Analysis of Aluminum Borate Ceramics via Solid-State Reaction Synthesis. Int. J. Appl. Ceram. Technol. 2019, 16 (6), 2457-2466.
(27) Whittaker, M. L.; Sohn, H.; Cutler, R. A. Oxidation Kinetics of Aluminum Diboride. J. Solid State Chem. 2013, 207, 163-169.
(28) Canova, K. L.; Zhang, Z. V.; Girolami, G. S.; Abelson, J. R. Superconformal Growth and Trench Filling Using a Consumable Inhibitor in Chemical Vapor Deposition of Hf1-xVxBy. J. Vac. Sci. Technol. Vac. Surf. Films 2021, 39 (1), 013402.
(29) Talukdar, T. K. Coating and Filling of Nanometer-Scale Structures Using Chemical Vapor Deposition. 2018.
(30) Goedde, D. M.; Girolami, G. S. A New Class of CVD Precursors to Metal Borides: Cr (B3H8) 2 and Related Octahydrotriborate Complexes. J. Am. Chem. Soc. 2004, 126 (39), 12230-12231.
(31) Fischer, R. X.; Kahlenberg, V.; Voll, D.; MacKenzie, K. J.; Smith, M. E.; Schnetger, B.; Brumsack, H.-J.; Schneider, H. Crystal Structure of Synthetic Al4B2O9: A Member of the Mullite Family Closely Related to Boralsilite. Am. Mineral. 2008, 93 (5-6), 918-927.
(32) SM, S.; BT, R.; J D, E.; C J, L. Barrier Coatings for Refractory Metals and Superalloys; Bettis Atomic Power Lab., 2006.

### ASPECTS AND COMBINATIONS

Aspect 1. A method for forming a diboride alloy coating on a surface via chemical vapor deposition, the method comprising:
contacting the surface with a boron-containing precursor and a boron-capturing agent;
heating the surface, the boron-containing precursor, and the boron-capturing agent to a temperature of less than or equal to 750° C.; and forming the diboride alloy coating on the surface.

Aspect 2. The method of aspect 1, wherein the boron-capturing agent comprises aluminum.

Aspect 3. The method of any of the preceding aspects, wherein the boron capturing agent is trimethylamine alane (TMAA).

Aspect 4. The method of any of the preceding aspects, wherein the diboride alloy coating is formed using at least some of the aluminum of the boron capturing agent.

Aspect 5. The method of any of the preceding aspects, wherein the boron-capturing agent comprises chromium or magnesium.

Aspect 6. The method of any of the preceding aspects, wherein the boron-containing precursor is Hf(BH₄)₄.

Aspect 7. The method of any one of aspects 1-5, wherein the boron-containing precursor is Ti(BH₄)₃(dme), wherein dme is 1,2-dimethoxyethane.

Aspect 8. The method of any one of aspects 1-5, wherein the boron-containing precursor is Zr(BH₄)₄.

Aspect 9. The method of any one of aspects 1-5, wherein the boron-containing precursor is Cr(B₃H₈)₂.

Aspect 10. The method of any of the preceding aspects, wherein the heating step comprises heating the surface, the boron-containing precursor, and the boron-capturing agent to a temperature of greater than 200° C.

Aspect 11. The method of any of the preceding aspects, wherein the heating step comprises heating the surface, the boron-containing precursor, and the boron-capturing agent to a temperature of 250 to 300° C.

Aspect 12. The method of any of the preceding aspects, wherein the contacting step occurs in a reaction chamber.

Aspect 13. The method of aspect 12, wherein during the contacting step, partial pressure of the boron-containing precursor inside the reaction chamber is maintained at 0.07 to 0.9 mTorr.

Aspect 14. The method of any one of aspects 12 or 13, wherein during the contacting step, partial pressure of the boron-capturing agent inside the reaction chamber is maintained at 0.01 to 0.06 mTorr.

Aspect 15. The method of any one of aspects 12-14, wherein during the contacting step, a ratio of the partial pressure of the boron-containing precursor to the partial pressure of the boron capturing agent is from 1.6 to 20.

Aspect 16. The method of any of aspects 12-15, wherein during the contacting step, the total pressure inside the reaction chamber is from 0.08 to 2 mTorr.

Aspect 17. The method of any of the preceding aspects, wherein the diboride alloy coating is predominately crystalline.

Aspect 18. The method of any of the preceding aspects, wherein the diboride alloy coating is nanocrystalline.

Aspect 19. The method of any of the preceding aspects, wherein the diboride alloy coating is a solid solution.

Aspect 20. The method of any of the preceding aspects, wherein the diboride alloy coating comprises aluminum.

Aspect 21. The method of any one of aspects 1-6 and 10-20, wherein the diboride alloy coating has the chemical formula Hf₁₋ₓAlₓB_{y}.

Aspect 22. The method of aspect 21, wherein x is from 0.3 to 0.6.

Aspect 23. The method of aspect 21 or 22, wherein x is about (±10%) 0.4.

Aspect 24. The method of any one of claims 21-23, wherein y is from 1.8 to 3.

Aspect 25. The method of any one of claims 21-24, wherein y is about (±10%) 2.

Aspect 26. The method of any one of aspects 1-5, 7 and 10-20, wherein the diboride alloy coating has the chemical formula Ti₁₋ₓAlₓB_{y}.

Aspect 27. The method of aspect 26, wherein x is from 0.3 to 0.6.

Aspect 28. The method of aspect 26 or 27, wherein x is about (±10%) 0.4.

Aspect 29. The method of any one of claims 26-28, wherein y is from 1.8 to 3.

Aspect 30. The method of any one of claims 26-29, wherein y is about (±10%) 2.

Aspect 31. The method of any one of aspects 1-5, 8 and 10-20, wherein the diboride alloy coating has the chemical formula Zr₁₋ₓAlₓB_{y}.

Aspect 32. The method of aspect 31, wherein x is from 0.3 to 0.6.

Aspect 33. The method of aspect 31 or 32, wherein x is about (±10%) 0.4.

Aspect 34. The method of any one of claims 31-33, wherein y is from 1.8 to 3.

Aspect 35. The method of any one of claims 31-34, wherein y is about (±10%) 2.

Aspect 36. The method of any one of aspects 1-5, 8 and 10-20, wherein the diboride alloy coating has the chemical formula Cr₁₋ₓAlₓB_{y}.

Aspect 37. The method of aspect 36, wherein x is from 0.3 to 0.6.

Aspect 38. The method of aspect 36 or 37, wherein x is about (±10%) 0.4.

Aspect 39. The method of any one of claims 36-38, wherein y is from 1.8 to 3.

Aspect 40. The method of any one of claims 36-39, wherein y is about (±10%) 2.

Aspect 41. The method of any of the previous aspects comprising heat treating the diboride alloy coating to improve hardness and/or crystallinity of the coating.

42. The method of aspect 41, wherein heat treating the coating comprises heating the coating in the absence of oxygen.

43. The method of aspect 42, wherein heat treating the coating comprises heating the coating to a temperature of 650 to 900° C. in the absence of oxygen.

44. A conformal coating formed by the method of any of the previous aspects.

45. The conformal coating of aspect 44, wherein the surface upon which the coating is formed comprises the inner surface of a channel, the channel having an aspect ratio of at least 1:10.

46. The conformal coating of aspect 44 or 45, wherein the conformal coating has a thickness of up to 250 nm.

47. A method for forming a diboride alloy coating on a surface via chemical vapor deposition, the method comprising:
contacting the surface with Hf(BH₄)₄ and trimethylamine alane (TMAA);
heating the surface, the Hf(BH₄)₄, and the TMAA to a temperature of less than or equal to 750° C.; and

forming the diboride alloy coating on the surface, wherein the diboride alloy coating has the chemical formula Hf₁₋ₓAlₓB_{y}.

### STATEMENTS REGARDING INCORPORATION BY REFERENCE AND VARIATIONS

All references throughout this application, for example patent documents including issued or granted patents or equivalents; patent application publications; and non-patent literature documents or other source material; are hereby incorporated by reference herein in their entireties, as though individually incorporated by reference, to the extent each reference is at least partially not inconsistent with the disclosure in this application (for example, a reference that is partially inconsistent is incorporated by reference except for the partially inconsistent portion of the reference).

The terms and expressions which have been employed herein are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments, exemplary embodiments and optional features, modification and variation of the concepts herein disclosed may be resorted to by those skilled in the art, and that such modifications and variations are considered to be within the scope of this invention as defined by the appended claims. The specific embodiments provided herein are examples of useful embodiments of the present invention and it will be apparent to one skilled in the art that the present invention may be carried out using a large number of variations of the devices, device components, methods steps set forth in the present description. As will be obvious to one of skill in the art, methods and devices useful for the present methods can include a large number of optional composition and processing elements and steps.

As used herein and in the appended claims, the singular forms “a”, “an”, and “the” include plural reference unless the context clearly dictates otherwise. Thus, for example, reference to “a cell” includes a plurality of such cells and equivalents thereof known to those skilled in the art. As well, the terms “a” (or “an”), “one or more” and “at least one” can be used interchangeably herein. It is also to be noted that the terms “comprising”, “including”, and “having” can be used interchangeably. The expression “of any of claims XX-YY” (wherein XX and YY refer to claim numbers) is intended to provide a multiple dependent claim in the alternative form, and in some embodiments is interchangeable with the expression “as in any one of claims XX-YY.”

When a group of substituents is disclosed herein, it is understood that all individual members of that group and all subgroups, including any isomers, enantiomers, and diastereomers of the group members, are disclosed separately. When a Markush group or other grouping is used herein, all individual members of the group and all combinations and subcombinations possible of the group are intended to be individually included in the disclosure. When a compound is described herein such that a particular isomer, enantiomer or diastereomer of the compound is not specified, for example, in a formula or in a chemical name, that description is intended to include each isomers and enantiomer of the compound described individual or in any combination. Additionally, unless otherwise specified, all isotopic variants of compounds disclosed herein are intended to be encompassed by the disclosure. For example, it will be understood that any one or more hydrogens in a molecule disclosed can be replaced with deuterium or tritium. Isotopic variants of a molecule are generally useful as standards in assays for the molecule and in chemical and biological research related to the molecule or its use. Methods for making such isotopic variants are known in the art. Specific names of compounds are intended to be exemplary, as it is known that one of ordinary skill in the art can name the same compounds differently.

Certain molecules disclosed herein may contain one or more ionizable groups [groups from which a proton can be removed (e.g., —COOH) or added (e.g., amines) or which can be quaternized (e.g., amines)]. All possible ionic forms of such molecules and salts thereof are intended to be included individually in the disclosure herein. With regard to salts of the compounds herein, one of ordinary skill in the art can select from among a wide variety of available counterions those that are appropriate for preparation of salts of this invention for a given application. In specific applications, the selection of a given anion or cation for preparation of a salt may result in increased or decreased solubility of that salt.

Every device, system, formulation, combination of components, or method described or exemplified herein can be used to practice the invention, unless otherwise stated.

Whenever a range is given in the specification, for example, a temperature range, a time range, or a composition or concentration range, all intermediate ranges and subranges, as well as all individual values included in the ranges given are intended to be included in the disclosure. It will be understood that any subranges or individual values in a range or subrange that are included in the description herein can be excluded from the claims herein.

All patents and publications mentioned in the specification are indicative of the levels of skill of those skilled in the art to which the invention pertains. References cited herein are incorporated by reference herein in their entirety to indicate the state of the art as of their publication or filing date and it is intended that this information can be employed herein, if needed, to exclude specific embodiments that are in the prior art. For example, when composition of matter are claimed, it should be understood that compounds known and available in the art prior to Applicant's invention, including compounds for which an enabling disclosure is provided in the references cited herein, are not intended to be included in the composition of matter claims herein.

As used herein, “comprising” is synonymous with “including,” “containing,” or “characterized by,” and is inclusive or open-ended and does not exclude additional, unrecited elements or method steps. As used herein, “consisting of” excludes any element, step, or ingredient not specified in the claim element. As used herein, 20 “consisting essentially of” does not exclude materials or steps that do not materially affect the basic and novel characteristics of the claim. In each instance herein any of the terms “comprising”, “consisting essentially of” and “consisting of” may be replaced with either of the other two terms. The invention illustratively described herein suitably may be practiced in the absence of any element or elements, limitation or limitations which is not specifically disclosed herein.

One of ordinary skill in the art will appreciate that starting materials, biological materials, reagents, synthetic methods, purification methods, analytical methods, assay methods, and biological methods other than those specifically exemplified can be employed in the practice of the invention without resort to undue experimentation. All art-known functional equivalents, of any such materials and methods are intended to be included in this invention. The terms and expressions which have been employed are used as terms of description and not of limitation, and there is no intention that in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

1. A method for forming a diboride alloy coating on a surface via chemical vapor deposition, the method comprising:
contacting the surface with a boron-containing precursor and a boron-capturing agent;
heating the surface, the boron-containing precursor, and the boron-capturing agent to a temperature of less than or equal to 750° C.; and
forming the diboride alloy coating on the surface.

2. The method of claim 1, wherein the boron-capturing agent comprises aluminum.

3. The method of claim 1, wherein the boron capturing agent is trimethylamine alane (TMAA).

4. The method of claim 1, wherein the diboride alloy coating is formed using at least some of the aluminum of the boron capturing agent.

5. The method of claim 1, wherein the boron-capturing agent comprises chromium or magnesium.

6. The method of claim 1, wherein the boron-containing precursor is Hf(BH₄)₄.

7. The method of claim 1, wherein the boron-containing precursor is Ti(BH₄)₃(dme), wherein dme is 1,2-dimethoxyethane.

8. The method of claim 1, wherein the boron-containing precursor is Zr(BH₄)₄.

9. The method of claim 1, wherein the boron-containing precursor is Cr(B₃H₈)₂.

10-20. (canceled)

21. The method of claim 1, wherein the diboride alloy coating has the chemical formula Hf₁₋ₓAlₓB_{y}.

22. The method of claim 21, wherein x is from 0.3 to 0.6.

23. (canceled)

24. The method of claim 21, wherein y is from 1.8 to 3.

25. (canceled)

26. The method of claim 1, wherein the diboride alloy coating has the chemical formula Ti₁₋ₓAlₓB_{y}.

27-30. (canceled)

31. The method of claim 1, wherein the diboride alloy coating has the chemical formula Zr₁₋ₓAlₓB_{y}.

32-35. (canceled)

36. The method of claim 1, wherein the diboride alloy coating has the chemical formula Cr₁₋ₓAlₓB_{y}.

37-40. (canceled)

41. The method of claim 1, comprising heat treating the diboride alloy coating to improve hardness and/or crystallinity of the coating.

42. (canceled)

43. The method of claim 41, wherein heat treating the coating comprises heating the coating to a temperature of 650 to 900° C. in the absence of oxygen.

44. A conformal coating formed by the method of claim 1.

45. The conformal coating of claim 44, wherein the surface upon which the coating is formed comprises the inner surface of a channel, the channel having an aspect ratio of at least 1:10.

46. The conformal coating of claim 44, wherein the conformal coating has a thickness of up to 250 nm.

47. A method for forming a diboride alloy coating on a surface via chemical vapor deposition, the method comprising:
contacting the surface with Hf(BH₄)₄ and trimethylamine alane (TMAA);
heating the surface, the Hf(BH₄)₄, and the TMAA to a temperature of less than or equal to 750° C.; and
forming the diboride alloy coating on the surface, wherein the diboride alloy coating has the chemical formula Hf₁₋ₓAlₓB_{y}.
